(19) United States
(12) Patent Application Publication
(10) Pub. No.: US 2024/0292619 A1
(43) Pub. Date: Aug. 29, 2024

(54) SEMICONDUCTOR STORAGE DEVICE AND METHOD FOR MANUFACTURING SEMICONDUCTOR STORAGE DEVICE

(71) Applicant: Kioxia Corporation, Minato-ku (JP)

(72) Inventors: Yasuaki NAKATA, Kuwana Mie (JP); Masayoshi TAGAMI, Kuwana Mie (JP); Koichi SAKATA, Yokkaichi Mie (JP); Miki TOSHIMA, Nagoya Aichi (JP)

(73) Assignee: Kioxia Corporation, Minato-ku (JP)

(21) Appl. No.: 18/586,775

(22) Filed: Feb. 26, 2024

(30) Foreign Application Priority Data
Feb. 28, 2023 (JP) 2023-029833

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A semiconductor storage device includes transistors disposed on a substrate; a first metal wiring layer disposed over the transistors at a first position, the first metal wiring layer including a first metal wiring; a stacked body, disposed above the first metal wiring layer, including a first conductive layers and first insulating layers alternately stacked; a pillar including a semiconductor layer that includes a first type impurity in an upper end and penetrates through the stacked body; and a second conductive layer disposed at a second position further from the substrate than the first position, overlapped with the first metal wiring or another metal wiring in the first metal wiring layer, and not electrically connected to any of the transistors, the first conductive layers, or the first metal wiring layer. The second conductive layer has a higher melting point than the first metal wiring.

### CROSS-REFERENCE TO RELATED APPLICATION(S)

This application is based upon and claims the benefit of priority from Japanese Patent Application No. 2023-029833, filed Feb. 28, 2023, the entire contents of which are incorporated herein by reference.

### FIELD

Embodiments described herein relate generally to a semiconductor storage device and a method for manufacturing the semiconductor storage device.

### BACKGROUND

In a semiconductor storage device such as a 3D nonvolatile memory, pillars are formed that penetrate a stacked body in which a plurality of conductive layers and a plurality of insulating layers are alternately stacked. At this time, in order to form an active layer at upper ends of the pillars, laser light or the like may be irradiated from above the semiconductor storage device. A part of the laser light may penetrate into the semiconductor storage device, causing damage such as melting the lower wiring layer.

### DESCRIPTION OF THE DRAWINGS

FIG. 1 is a cross-sectional view showing a schematic configuration example of a semiconductor storage device according to an embodiment;

FIGS. 2A to 2C are a cross-sectional view showing an example of the configuration of the semiconductor storage device according to an embodiment;

FIGS. 3A to 3C are a schematic diagram showing a positional relationship between a stacking direction of a plurality of wiring layers and a plurality of dummy layers in the semiconductor storage device according to an embodiment;

FIG. 4A and FIG. 4B are a diagram sequentially showing a part of the procedure of a method for manufacturing the semiconductor storage device according to an embodiment;

FIG. 5A and FIG. 5B are a diagram sequentially showing a part of the procedure of the method for manufacturing the semiconductor storage device according to an embodiment;

FIG. 6A and FIG. 6B are a diagram sequentially showing a part of the procedure of the method for manufacturing the semiconductor storage device according to an embodiment;

FIG. 7A and FIG. 7B are a diagram sequentially showing a part of the procedure of the method for manufacturing the semiconductor storage device according to an embodiment;

FIG. 8A and FIG. 8B are a diagram sequentially showing a part of the procedure of a method for manufacturing the semiconductor storage device according to an embodiment;

FIG. 9A and FIG. 9B are a diagram sequentially showing a part of the procedure of the method for manufacturing the semiconductor storage device according to an embodiment;

FIG. 10A and FIG. 10B are a diagram sequentially showing a part of the procedure of the method for manufacturing the semiconductor storage device according to an embodiment;

FIG. 11A and FIG. 11B are a diagram sequentially showing a part of the procedure of the method for manufacturing the semiconductor storage device according to an embodiment;

FIG. 12A and FIG. 12B are a diagram sequentially showing a part of the procedure of the method for manufacturing the semiconductor storage device according to an embodiment;

FIG. 13A and FIG. 13B are a diagram sequentially showing a part of the procedure of the method for manufacturing the semiconductor storage device according to an embodiment;

FIG. 14A and FIG. 14B are a diagram sequentially showing a part of the procedure of the method for manufacturing the semiconductor storage device according to an embodiment;

FIG. 15A and FIG. 15B are a diagram sequentially showing a part of the procedure of the method for manufacturing the semiconductor storage device according to an embodiment;

FIG. 16 is a diagram sequentially showing a part of the procedure of the method for manufacturing the semiconductor storage device according to an embodiment;

FIG. 17 is a schematic diagram showing a process of irradiating laser light for a method for manufacturing the semiconductor storage device according to an embodiment;

FIGS. 18Aa to 18Bd are a cross-sectional view showing a part of a process of connecting contacts and source side wiring layers in the semiconductor storage device according to an embodiment and a comparative example;

FIG. 19 is a schematic diagram showing an example of the configuration of a dummy layer in a semiconductor storage device according to a modification of an embodiment;

FIG. 20 is a cross-sectional view showing an example of another configuration of a semiconductor storage device according to a modification of an embodiment; and

FIGS. 21Aa to 21Bc is a schematic diagram showing analysis results of optical and heat transfer engineering simulations of the semiconductor storage device according to an embodiment, a modification, and a comparative example.

### DETAILED DESCRIPTION

Embodiments provide a semiconductor storage device that can prevent damage to wiring layers caused by laser light irradiation, and a method for manufacturing the semiconductor storage device.

In general, according to one embodiment, a semiconductor storage device may include a substrate; a plurality of transistors disposed on the substrate; a first metal wiring layer disposed over the plurality of transistors at a first position in a first direction perpendicular to the substrate, the first metal wiring layer including a first metal wiring; a stacked body, disposed above the first metal wiring layer, including a plurality of first conductive layers and a plurality of first insulating layers alternately stacked on top of one another in the first direction, wherein the stacked body is overlapped with the first metal wiring in the first direction; a pillar including a semiconductor layer that includes a first type impurity in an upper end and penetrates through the stacked body in the first direction, wherein the semiconductor layer is electrically connected to the plurality of transistors via the first metal wiring; and a second conductive layer disposed at a second position further from the substrate than the first position in the first direction, overlapped with the first metal wiring or another metal wiring in the first metal wiring layer in the first direction, and not electrically connected to any of the plurality of transistors, the plurality of first conductive layers, or the first metal wiring layer. The second conductive layer includes at least one of a metal layer or a semiconductor layer, the second conductive layer having a higher melting point than the first metal wiring.

Hereinafter, embodiments of the present disclosure will be described in detail with reference to the drawings. It is to be noted that the present disclosure is not limited to the embodiments described below. In addition, components in the following embodiments include components that can be easily conceived by a person skilled in the art, and those that are substantially the same.

### Configuration Example of Semiconductor Storage Device

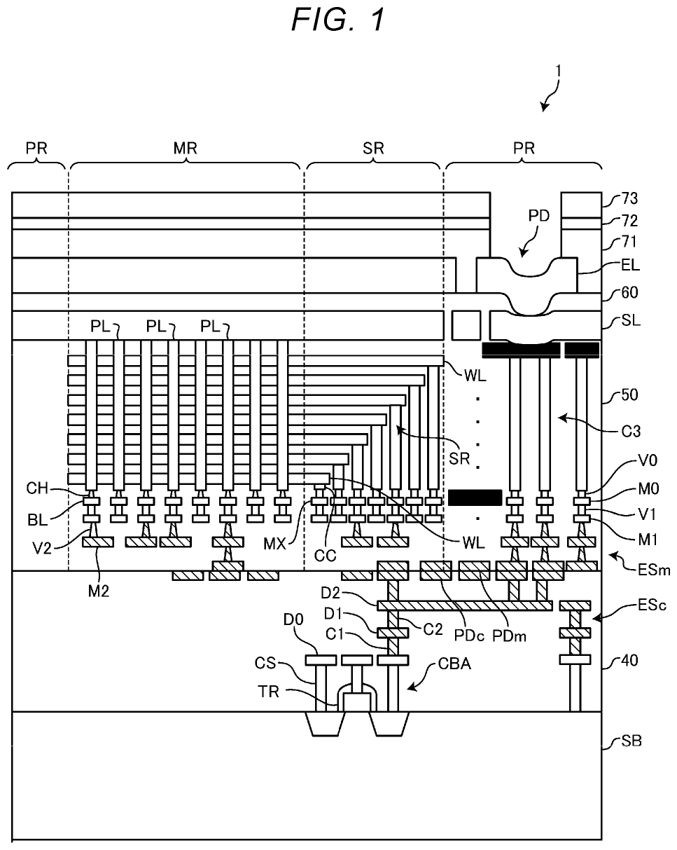

FIG. 1 is a cross-sectional view showing a schematic configuration example of a semiconductor storage device 1 according to an embodiment. Meanwhile, in FIG. 1, hatching is omitted in consideration of the ease of viewing the drawing.

As shown in FIG. 1, a semiconductor storage device 1 includes a peripheral circuit CBA, a plurality of word lines WL, a source side wiring layer SL, and an electrode layer EL in this order above a semiconductor substrate SB. It is to be noted that, in the following description, the side on which the semiconductor substrate SB is disposed is assumed to be the lower side of the semiconductor storage device 1.

The semiconductor substrate SB is a silicon substrate, for example. The peripheral circuit CBA including a transistor TR and the like is disposed on the semiconductor substrate SB. The peripheral circuit CBA contributes to the operation of a memory cell, which will be described below.

The peripheral circuit CBA is covered with an insulating layer 40. An edge seal ESc is disposed in the insulating layer 40 around the peripheral circuit CBA, extending through the insulating layer 40 from the semiconductor substrate SB side to the surface side of the insulating layer 40. A plurality of word lines WL are stacked above the insulating layer 40. The plurality of word lines WL are covered with an insulating layer 50, and are joined to the insulating layer 40 covering the peripheral circuit CBA via the insulating layer 50. The insulating layer 50 also extends around the plurality of word lines WL. Contacts C3, edge seals ESm, etc., which extend through the insulating layer 50 in the stacking direction of the plurality of word lines WL, are disposed in the surrounding insulating layer 50.

Memory regions MR are disposed on the plurality of word lines WL, and staircase regions SR are disposed at the ends of the plurality of word lines WL. Peripheral regions PR are disposed outside the plurality of word lines WL.

A plurality of pillars PL penetrating the word lines WL in the stacking direction are disposed in the memory regions MR. Memory cells are formed at the intersections of the pillars PL and the word lines WL. Accordingly, the semiconductor storage device 1 is configured as a 3D nonvolatile memory in which memory cells are disposed three-dimensionally in the memory regions MR, for example.

In the staircase regions SR, the ends of the plurality of word lines WL are processed into a staircase shape. As a result, the ends of the plurality of word lines WL widen toward the outer regions of the plurality of word lines WL along a direction toward the source side wiring layer SL. Contacts CC are connected to each layer of the plurality of word lines WL in a staircase shape.

By these contacts CC, the word lines WL stacked in multiple layers are individually drawn out. From these contacts CC, a write voltage, a read voltage, etc. are applied to the memory cells in the memory regions MR at the center of the plurality of word lines WL via the word lines WL positioned at the same height position as the memory cells. Various voltages applied to the memory cells from the contacts CC are controlled by the peripheral circuits CBA electrically connected to these contacts CC.

The source side wiring layer SL is disposed above the plurality of word lines WL. The electrode layer EL is disposed on the source side wiring layer SL with an insulating layer 60 such as a silicon oxide layer interposed therebetween. The electrode layer EL has a pad region PD that partially penetrates the insulating layer 60 and maintains electrical continuity with the source side wiring layer SL. The source side wiring layer SL is a tungsten layer, etc. for example, and the electrode layer EL is an aluminum layer, etc., for example.

Accordingly, power can be supplied from the outside of the semiconductor storage device 1 to the source side wiring layer SL via the electrode layer EL. The power from the source side wiring layer SL is supplied to the peripheral circuits CBA via the contacts C3, etc.

The electrode layer EL except the pad region PD is covered with a plurality of insulating layers 71 to 73. The plurality of insulating layers 71 to 73 are stacked in this order from the electrode layer EL side. For example, the insulating layer 71 is a silicon oxide layer, etc., the insulating layer 72 is a silicon nitride layer, etc., and the insulating layer 73 is a polyimide layer, etc.

In addition, the semiconductor storage device 1 includes various wiring layers. These wiring layers are disposed at different height positions, and the wiring layers at different height positions are connected to each other by the contacts or vias, for example.

A plurality of wiring layers electrically connect various structures on the side of the plurality of word lines WL and the peripheral circuits CBA in the insulating layers 40 and 50 between the peripheral circuits CBA and the plurality of word lines WL.

For example, in the insulating layer 40, a contact CS, a wiring layer D0, a via C1, a wiring layer D1, a via C2, a wiring layer D2, etc. are disposed in order from the transistor TR side of the peripheral circuit CBA toward the surface side of the insulating layer 40, and transistor TR and the like are electrically connected to an electrode pad PDc disposed on the surface of insulating layer 40. The electrode pad PDc is connected to an electrode pad DPm on the surface of insulating layer 50, which will be described below. As a result, various structures on the word line WL side and the peripheral circuit CBA are electrically connected to each other.

The wiring layers disposed in the insulating layer 40, or more particularly, the wiring layers disposed at a height position near the peripheral circuit CBA are tungsten wirings, etc., for example. The wiring layers above these tungsten wirings are copper wirings, etc., for example.

For example, in the insulating layer 50, a plug V0, a wiring layer M0, a plug V1, a wiring layer M1, a plug V2, a wiring layer M2, etc. are disposed in order from the word line WL side toward the surface side of the insulating layer 50, and various structures on the word line WL side are electrically connected to the electrode pads PDm disposed on the surface of the insulating layer 50. In addition, the insulating layer 50 includes a plug CH disposed in the same layer as the plug V0, a wiring layer MX, and a bit line BL disposed in the same layer as the wiring layer M0, and the like.

The wiring layers, of the wiring layers disposed in the insulating layer 50, disposed at a height position near the plurality of word lines WL are tungsten wirings, etc., for example. The wiring layers below these tungsten wirings are copper wirings, etc., for example.

In FIG. 1, the wiring layers disposed in the insulating layers 40 and 50, or more particularly, the wiring layers that are copper wiring and the like are shown hatched. That is, in the example of FIG. 1, the contact CS and wiring layer D0 in the insulating layer 40 are tungsten wirings, and the vias C1 and C2, wiring layers D1 and D2, and the electrode pad PDc are copper wirings. Furthermore, the plugs CH, V0, V0, and V1, the bit line BL, the wiring layers M0, MX, and M1 in the insulating layer 50 are tungsten wirings, and the plug V2, the wiring layer M2, and the electrode pad PDm are copper wirings.

Among these hatched copper wirings, the vias C1 and C2, the wiring layers D1 and D2, the plug V2, and the wiring layer M2, which overlap with the plurality of word lines WL in the stacking direction, are examples of first metal wirings. In addition, among these hatched copper wirings, the vias C1 and C2, the wiring layers D1 and D2, the electrode pads PDc and PDm, the plug V2, the wiring layer M2, and the electrode pad PDm, which do not overlap with the plurality of word lines WL in the stacking direction, are examples of second metal wirings. The copper wiring including these first and second metal wirings are an example of a first metal wiring layer.

Further, among the tungsten wirings disposed in the insulating layer 50, the plugs CH, V0, and V0, the bit line BL, and the wiring layers M0 and MX are an example of a second metal wiring layer, and the plug V1 and the wiring layer M1 are an example of a third metal wiring layer. Further, the source side wiring layer SL described above is an example of a fourth metal wiring layer.

In addition to the wiring layers described above, a dummy layer is also disposed in the insulating layer 50. The dummy layer is basically a metal layer such as a tungsten layer that is in a floating state and does not contribute to the electrical operation of the semiconductor storage device 1. In FIG. 1, the dummy layer is shown in black.

A plurality of dummy layers are also disposed at different height positions in the insulating layer 50. Some of the plurality of dummy layers are disposed at the same height position as the wiring layer such as the tungsten wiring disposed in the insulating layer 50, for example. Further, other dummy layers are disposed at the upper ends of the contacts C3 and edge seals ESm positioned in the peripheral regions PR, for example. The dummy layer positioned at the same height position as the tungsten wiring in the insulating layer 50 is an example of a second conductive layer, and the dummy layer at the upper end of the contact C3 and edge seal ESm is an example of a fifth conductive layer.

It is noted that dummy layers positioned at different height positions may not be connected to each other by contacts or vias, for example.

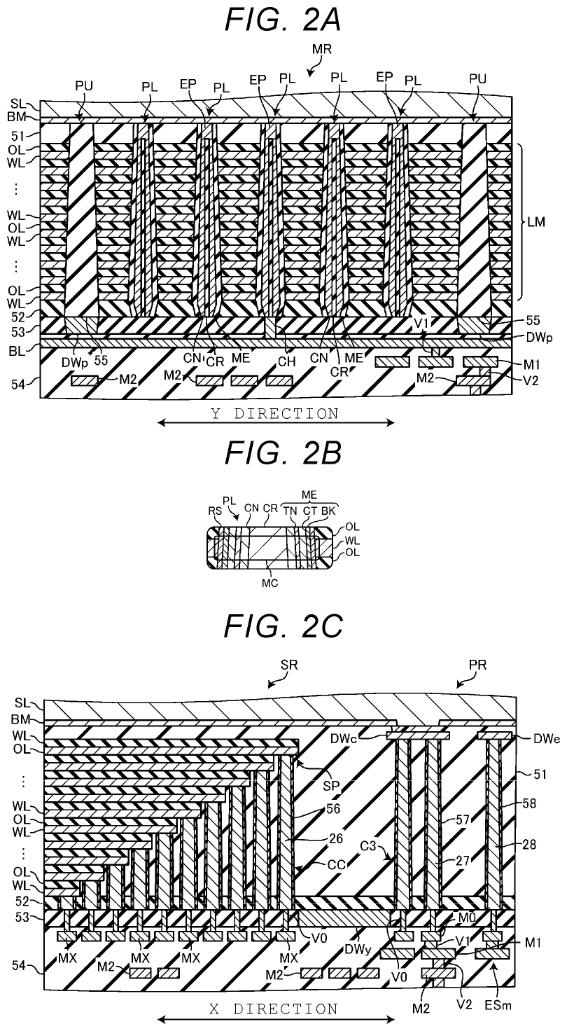

Next, a detailed configuration example of the semiconductor storage device 1 will be described using FIG. 2. FIG. 2 is a cross-sectional view showing an example of the configuration of the semiconductor storage device 1 according to an embodiment.

More specifically, FIG. 2A is a cross-sectional view of the memory region MR along the Y direction. FIG. 2B is a partially enlarged view showing a cross section of the pillar PL disposed in the memory region MR. FIG. 2C is a cross-sectional view of the staircase region SR and the peripheral region PR along the X direction.

Further, in FIGS. 2A and 2C, the structures below the insulating layer 50 such as the semiconductor substrate SB and the peripheral circuit CBA, and the structures above the insulating layer 60 such as the electrode layer EL are omitted.

It is to be noted that, in the description, both the X direction and the Y direction are directions along the plane of the word line WL, and the X direction and the Y direction are orthogonal to each other. Further, the direction in which the word line WL is electrically drawn out may be referred to as a second direction, and the second direction is a direction along the X direction. Further, a direction intersecting the second direction may be referred to as a third direction, and the third direction is a direction along the Y direction. It is noted that, since the semiconductor storage device 1 may include manufacturing errors, the second direction and the third direction are not necessarily orthogonal.

Furthermore, in the description, the stacking direction in which the word lines WL of the stacked body LM are stacked may be referred to as a first direction. The third direction intersects the second and third directions described above.

As shown in FIGS. 2A and 2C, the stacked body LM is disposed above the peripheral circuit CBA with insulating layers 54 to 52 interposed therebetween. In the staircase region SR of the stacked body LM, an insulating layer 51 is further disposed between the insulating layer 52 and the stacked body LM. These insulating layers 51 to 54 form a part of the insulating layer 50 in FIG. 1. In addition, the insulating layers 51 to 54 are examples of a second insulating layer.

The stacked body LM above the insulating layers 51 to 54 has a structure in which a plurality of word lines WL and a plurality of insulating layers OL are alternately stacked one layer at a time. One or more select gate lines may be stacked in layers further below the word line WL in the lowermost layer of the stacked body LM, and further above the word line WL in the uppermost layer of the stacked body LM, respectively, with the insulating layer OL interposed therebetween. The number of the stacked word lines WL and the select gate lines in the stacked body LM is freely chosen.

Each of the plurality of word lines WL and the select gate lines is a tungsten layer or a molybdenum layer, for example. These word lines WL are an example of a plurality of first conductive layers. The select gate lines disposed above and below the word line WL may be provided in the plurality of first conductive layers. Each of the plurality of insulating layers OL is a silicon oxide layer, for example.

On the stacked body LM, a barrier metal layer BM and a source side wiring layer SL are disposed in this order from the insulating layer 51 side with the insulating layer 51 interposed therebetween. The barrier metal layer BM is a titanium nitride layer or a tantalum nitride layer, for example. The source side wiring layer SL is a tungsten layer, as described above, for example.

As shown in FIG. 2A, the stacked body LM is divided in the Y direction by a plurality of plate-shaped parts PU.

The plurality of plate-shaped parts PU are disposed side by side in the Y direction and extend in a direction along the stacking direction and the X direction of the stacked body LM. That is, the plate-shaped parts PU extend continuously in the stacked body LM from one end in the X direction to the other end of the stacked body LM. Accordingly, the stacked body LM is divided in the Y direction.

More specifically, the plate-shaped part PU is an insulating layer 55 such as a silicon oxide layer that extends from the upper surface of the insulating layer 51 disposed on the stacked body LM, penetrates the stacked body LM and the insulating layer 52, and reaches the insulating layer 53. A dummy layer DWp disposed in the insulating layer 53 is connected to the lower end of the plate-shaped part PU.

In the memory region MR, a plurality of pillars PL extending in the stacked body LM in the stacking direction of the stacked body LM are disposed in a distributed manner between the plate-shaped parts PU adjacent to each other in the Y direction. More specifically, the pillar PL penetrates through the stacked body LM and the insulating layer 52 and reaches the insulating layer 53 from the upper surface of the insulating layer 51 disposed on the stacked body LM.

For example, the plurality of pillars PL are disposed in a staggered manner when viewed from the stacking direction of the stacked body LM. For example, each pillar PL has a circular shape, an oval shape, or an oval shape as a cross-sectional shape along the stacking direction of the stacked body LM, that is, along the XY plane.

Each of the plurality of pillars PL includes a memory layer ME and a channel layer CN in order from the outer peripheral side of the pillar PL. A further inner region of the channel layer CN is filled with a core layer CR. Further, each of the plurality of pillars PL has an active layer EP at the upper end.

As shown in FIG. 2B, the memory layer ME has a multilayer structure in which a block insulating layer BK, a charge storage layer CT, and a tunnel insulating layer TN are stacked in this order from the outer peripheral side of the pillar PL. The block insulating layer BK on the outermost circumference of the memory layer ME is covered with an etch stopper layer RS. That is, the entire sidewall of the pillar PL is covered with the etch stopper layer RS.

The block insulating layer BK, the tunnel insulating layer TN, and the core layer CR of the memory layer ME are silicon oxide layers, for example. The charge storage layer CT of the memory layer ME is a silicon nitride layer, for example. The channel layer CN is a semiconductor layer such as a polysilicon layer or an amorphous silicon layer, for example. The etch stopper layer RS outside the pillar PL is a silicon oxynitride layer, for example.

The active layer EP is a polysilicon layer or the like containing an N-type dopant (impurity) such as phosphorus, and is connected, via the barrier metal layer BM described above, to the source side wiring layer SL at the upper end, and to the upper end of the channel layer CN at the lower end. The lower end of the channel layer CN is connected to the bit line BL extending in the Y direction in the insulating layer 54 via the plug CH penetrating the insulating layer 53.

It is to be noted that, in FIG. 2A, the plug CH is connected only to the pillar PL, of the plurality of pillars PL disposed side by side in the Y direction, that is in the center of the drawing. The plugs CH are connected to the other pillars PL at positions different from the cross section shown in FIG. 2A, respectively.

With the configuration as described above, the memory cell MC is formed in a portion facing the word line WL on the side surface of the pillar PL. By applying a predetermined voltage from the word line WL, data is written to and read from the memory cell MC. As will be described below, the bit line BL is electrically connected to the peripheral circuit CBA, and data from the memory cell MC is read out to a sense amplifier in the peripheral circuit CBA via the bit line BL.

In the description, in the extending direction of the pillar PL, the side having the active layer EP is defined as the upper side of the semiconductor storage device 1, and the side connected to the bit line BL via the plug CH is defined as the lower side of the semiconductor storage device 1.

As shown in FIG. 2C, the staircase region SR has a staircase portion SP which is a plurality of word lines WL and a plurality of insulating layers OL processed into a staircase shape. Each terrace surface of the staircase portion SP having a staircase shape is a lower surface of the word line WL of each layer, that is, a surface facing the insulating layer 52 side below the stacked body LM.

More specifically, as the distance from the memory region MR on the left side of the paper increases, the word line WL closer to the source side wiring layer SL forms the terrace surface of the staircase portion SP. The insulating layer 51 is interposed between each terrace surface of the staircase portion SP and the insulating layer 52 facing each terrace surface.

The contact CC penetrating through the insulating layers 52 and 51 is connected to the word line WL forming each layer of the staircase portion SP. The contact CC includes an insulating layer 56 covering an outer periphery of the contact CC, and a conductive layer 26 such as a tungsten layer filled inside the insulating layer 56. The conductive layer 26 is connected at an upper end to one of the word lines WL, and is connected at a lower end to the wiring layer MX disposed in the insulating layer 54 through the plug V0 penetrating the insulating layer 53.

With this configuration, the word line WL of each layer can be electrically drawn out. That is, as will be described below, the wiring layer MX is electrically connected to the peripheral circuit CBA, and a predetermined voltage is applied from a row decoder in the peripheral circuit CBA to the memory cell MC corresponding to each word line WL via the wiring layer MX, so that the memory cell MC can be operated as a storage element.

The contact C3 and the edge seal ESm extending in the stacking direction of the stacked body LM in the insulating layer 51 are disposed in the insulating layer 51 outside the staircase region SR of the stacked body LM.

More specifically, the contact C3 extends downward in the stacking direction from a height position in the insulating layer 51 above the height position of the upper surface of the stacked body LM, penetrates the insulating layer 52, and reaches the insulating layer 53.

Further, the contact C3 includes an insulating layer 57 covering the outer periphery of the contact C3, and a conductive layer 27 such as a tungsten layer filled inside the insulating layer 57. The conductive layer 27 is connected at an upper end to the source side wiring layer SL through the dummy layer DWc, and is connected at a lower end to the wiring layer M0 disposed in the insulating layer 54 through the plug V0 penetrating the insulating layer 53.

With this configuration, the contact C3 supplies the external electrode applied to the electrode layer EL to the peripheral circuit CBA.

The edge seal ESm is disposed on the insulating layer 51 further outer than the contact C3. The edge seal ESm is disposed so as to surround the stacked body LM when viewed from the stacking direction of the stacked body LM, and prevents cracking and chipping of the semiconductor storage device 1 and the incorporation of impurities into the semiconductor storage device 1 when the semiconductor storage device 1 is diced into individual pieces at the final stage of the manufacturing process.

The edge seal ESm is disposed at the height position between the upper and lower ends of the contact C3 in the insulating layers 51 and 52, at the height position of the plugs CH and V0 in the insulating layer 53 described above, at the height position of the bit line BL and wiring layer MX in the insulating layer 54 described above, and at the height position of the plug V1 and the wiring layer M1 in the insulating layer 54 to be described below.

At the same height position as the contact C3, the edge seal ESm has the same layer structure as the contact C3, for example. That is, the edge seal ESm includes an insulating layer 58 disposed on the sidewall and a conductive layer 28 such as a tungsten layer filled inside the insulating layer 58.

Furthermore, at the same height position as the wiring layers MX and M1, the plugs V0, V1, etc., the edge seal ESm has the same layer structure as these wiring layers MX, M1, plugs V0, V1, etc., which will be described below.

In this way, the edge seal ESm extending from above the insulating layer 51 into the insulating layer 54 prevents the propagation of cracks toward the center of the semiconductor storage device 1 from the cut surface by dicing, the generation of cracks or chips in the semiconductor storage device 1, or the incorporation of impurities into the semiconductor storage device 1.

Further, the upper end of the edge seal ESm is connected to the dummy layer DWe. The dummy layer DWe is disposed at the same height position as the dummy layer DWc at the upper end of the contact C3 described above, but is not connected to the source side wiring layer SL, for example.

In addition, a dummy layer DWy is disposed in a region between the plugs V0 connected to the contacts CC and C3 in the insulating layer 53, respectively.

Furthermore, the edge seal ESc disposed in the insulating layer 40 on the peripheral circuit CBA side is disposed at a position overlapping with the edge seal ESm in the vertical direction, for example. That is, the edge seal ESc surrounds the peripheral circuit CBA when viewed from the upper surface side of the insulating layer 40, and is also disposed over the height positions of the plurality of wiring layers D0, D1, D2, contacts CS and vias C1, C2 in the insulating layer 40.

In the insulating layers 52 to 54 below the stacked body LM, a plurality of wiring layers MX, M0, M1, M2, etc. including the bit lines BL, the wiring layers MX, etc. described above, are disposed at different height positions. The stacked body LM and each structure disposed around the stacked body LM are electrically connected to the peripheral circuit CBA via these wiring layers MX, M0, M1, M2, etc. disposed at different height positions.

For example, parts of the plug CH connected to the pillar PL, the plug V0 connected to the contacts CC and C3, and the edge seal ESm are all disposed in the insulating layer 53 and are positioned at the same height.

Parts of the bit line BL connected to the plug CH of the pillar PL, the wiring layer MX connected to the plug V0 of the contact CC, the wiring layer M0 connected to the plug V0 of the contact C3, and the edge seal ESm are all disposed at the same height position in the insulating layer 54.

Furthermore, the bit line BL and the wiring layers MX and M0 are connected to the plug V1 positioned below, and a plurality of plugs V1 are connected to the wiring layer M1 positioned further below. Parts of the plurality of plugs V1 and the edge seal ESm are all disposed at the same height position in the insulating layer 54. The lower ends of a plurality of wiring layers M1 and the edge seal ESm are all disposed at the same height position in the insulating layer 54.

Likewise, the plurality of wiring layers M1 are connected to the plugs V2 positioned below, and the plurality of plugs V2 are connected to the wiring layer M2 positioned further below. In this way, each structure such as the pillar PL and the contacts CC and C3, etc. is sequentially connected to several layers of the bit lines BL, the wiring layers MX, M0, M1, M2, . . . , the plugs CH, V0, V1, V2, . . . , etc. toward the lower surface of the insulating layer 54 joined to the insulating layer 40 on the peripheral circuit CBA side.

Among these bit lines BL, wiring layers MX, M0, M1, M2, . . . , and plugs CH, V0, V1, V2, . . . , etc., the wiring layer M1, and the wiring layers MX and M0 and the plugs CH, V0 and V1 disposed above the wiring layer M1 are tungsten wirings, etc., for example. Parts of the edge seal ESm disposed at the same height position as the wiring layers MX, M0, M1, and the plugs CH, V0, V1 are also the tungsten layer, etc., configured in the same manner as these wiring layers MX, M0, M1 and plugs CH, V0, and V1.

Further, in the insulating layers 51 and 53, a plurality of dummy layers DWp, DWy, DWc, and DWe are disposed at different height positions.

The plurality of dummy layers DWp and DWy are disposed at the same height position as the plug CH that connects the pillar PL and the bit line BL, as the plug V0 that connects the contacts CC and C3 and the wiring layers MX and M0, etc., for example. The plurality of dummy layers DWp and DWy are the example of the second conductive layer.

As described above, the dummy layers DWc and DWe connected to the lower ends of the contact C3 and the edge seal ESm, respectively, are disposed at a height position above the stacked body LM and at the same height position in the insulating layer 51, as described above.

In this way, the plurality of dummy layers DWp, DWy, DWc, and DWe are also disposed above the wiring layer M1, and are tungsten layers, etc., for example. It is noted that, except for the dummy layer DWc that connects the contact C3 and the source side wiring layer SL, the plurality of dummy layers DWp, DWy, and DWe are in a floating state without electrical continuity with the other parts.

Meanwhile, the wiring layers M2, . . . , the plugs V2, . . . , etc. disposed below the wiring layer M1 are copper wirings, etc., for example. Above the wiring layer M2, . . . , the plug V2, . . . , etc., and the wiring layer etc. to be described below on the peripheral circuit CBA side, there are any of the word line WL, the wiring layers MX, M0, M1, M2, . . . , and the dummy layers DWp, DWy, DWc, and DWe of the stacked body LM all disposed at positions overlapping in the stacking direction of the stacked body LM.

Tungsten W contained in the bit line BL, the wiring layers MX, M1, M0, the plugs CH, V0, V1, and the dummy layers DWp, DWy, DWc, DWe, etc. has a higher melting point and a lower atomic mobility than copper Cu contained in the wiring layer M2, . . . , the plug V2, . . . , etc. Atomic mobility is the degree of ease with which a metal component moves in a nonmetal such as an insulating layer. In other words, metals with higher atomic mobility move more easily in nonmetals.

Moreover, above the wiring layers D1, D2, . . . , the vias C1, C2, . . . , the electrode pads PDc and PDm, and the edge seal ESc on the peripheral circuit CBA side, which partially include a copper layer, etc., any of the word line WL, the wiring layers MX, M0, M1, M2, . . . , and the dummy layers DWp, DWy, DWc, and DWe of the stacked body LM are disposed at positions overlapping in the stacking direction of the stacked body LM.

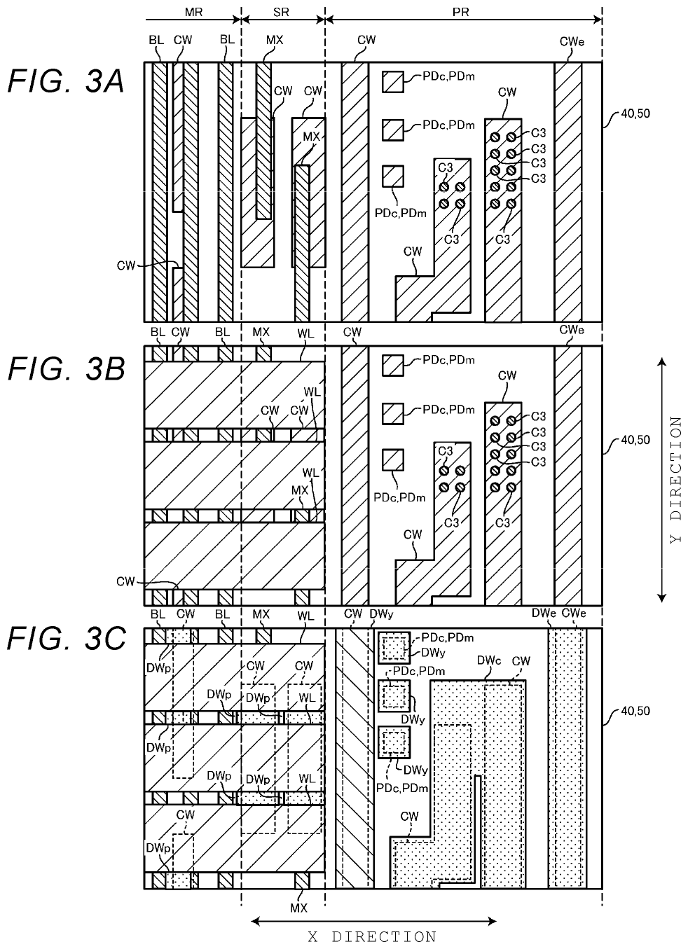

FIG. 3 shows the positional relationship in the stacking direction between the wiring layers D0, D1, D2, . . . , the contacts CS and vias C1, C2, . . . , the electrode pads PDc, etc. on the peripheral circuit CBA side, the bit line BL, the wiring layers MX, M0, M1, M2, . . . , the plugs CH, V0, V1, V2, . . . , the electrode pad PDm, etc. on the stacked body LM side, and the plurality of dummy layers DWp, DWy, DWc, and DWe.

FIG. 3 is a schematic diagram showing the positional relationship in the stacking direction between a plurality of copper wirings CW and a plurality of dummy layers DW in the semiconductor storage device 1 according to an embodiment. FIG. 3 shows a predetermined layer of the semiconductor storage device 1 viewed from above.

More specifically, FIG. 3A shows a plurality of wiring layers disposed over a plurality of layers between the peripheral circuit CBA and the stacked body LM when viewed from above. That is, FIG. 3A shows a plurality of wiring layers that are not disposed in the same XY cross section.

These wiring layers include at least part of the bit line BL, the wiring layers MX, M0, M1, M2, . . . , the plugs CH, V0, V1, V2, . . . , the electrode pads PDc and PDm, the wiring layers D0, D1, D2, . . . , the contact CS, and the vias C1, C2, . . . . It is noted that FIG. 3A does not show all of the bit line BL, the wiring layers MX, M0, M1, M2, . . . , the plugs CH, V0, V1, V2, . . . , the electrode pads PDc and PDm, the wiring layers D0, D1, D2, . . . , the contacts CS, and the vias C1, C2, . . . .

Further, FIG. 3B shows the word lines WL of the stacked body LM, overlapped on the wiring layers shown in FIG. 3A when viewed from above. FIG. 3C shows a plurality of dummy layers DW, overlapped on the wiring layers and word lines WL shown in FIG. 3B when viewed from above.

As shown in FIG. 3A, in the plurality of layers between the peripheral circuit CBA and the stacked body LM, the tungsten wirings such as a plurality of bit lines BL extending in the direction along the Y direction, and a plurality of copper wirings CW positioned below the plurality of bit lines BL are disposed in the memory region MR of the stacked body LM. The tungsten wiring such as the wiring layer MX connected to the contact CC and a plurality of copper wirings CW positioned below the wiring layer MX are disposed in the staircase region SR of the stacked body LM.

In addition, the plurality of copper wirings CW is either the wiring layers M2, . . . , and the plugs V2, . . . , on the stacked body LM side, or the wiring layers D1, D2, . . . , the vias C1, C2, . . . , etc. on the peripheral circuit CBA side.

In addition, in the plurality of layers between the peripheral circuit CBA and the stacked body LM, the copper wirings such as the electrode pads PDm and PDc that electrically connect each structure of the multilayer body LM and the peripheral circuit CBA, the copper wirings CW that are electrically connected to the plurality of contacts C3, other copper wirings CW, and a copper layer CWe that is part of the edge seal ESc, are disposed in the peripheral region PR outside the stacked body LM. In addition, the copper layer CWe, which is a part of the edge seal ESc, is disposed in a frame shape surrounding the peripheral circuit CBA, for example.

In the memory region MR and the staircase region SR of the stacked body LM, and in the peripheral region PR of the semiconductor storage device 1, the copper wiring CW, the electrode pads PDm and PDc, and part of the copper layer CWe overlap with the plurality of bit lines BL, the wiring layers MX, M0, and M1, and the tungsten wirings such as the plugs CH, V0, and V1 in the stacking direction.

As shown in FIG. 3B, the word lines WL of the stacked body LM are divided into a plurality of parts in the Y direction by the plate-shaped parts PU as described above, and the word lines WL are disposed side by side in the Y direction. That is, the space between the word lines WL disposed side by side in the Y direction shown in FIG. 3B corresponds to positions at which the plate-shaped parts PU are disposed. A further part of the copper wiring CW disposed in the memory region MR and the staircase region SR also overlaps in the stacking direction with the word line WL of the stacked body LM, which is the tungsten layer or the like.

As shown in FIG. 3C, the plurality of dummy layers DWp, DWy, DWc, and DWe are disposed at positions overlapping with the copper wiring CW, the electrode pads PDm, PDc, and the further part of the copper layer CWe in the stacking direction. In other words, the parts of the copper wiring CW and the like that overlap with the dummy layers DWp, DWy, DWc, and DWe in the stacking direction are parts that do not overlap with the plurality of bit lines BL and the tungsten wirings such as the wiring layer MX, nor with the word lines WL of the stacked body LM.

When viewed from the stacking direction of the stacked body LM, the plurality of dummy layers DWp, DWy, DWc, and DWe are designed to have a larger area than the corresponding parts of the copper wiring CW, the electrode pads PDm and PDc, and the copper layer CWe.

That is, the plurality of dummy layers DWp overlap in the stacking direction with the copper wiring CW parts that are disposed at the lower ends of the plate-shaped parts PU and that do not overlap with the bit lines BL, the wiring layers MX, the word lines WL, etc., as described above. The area of these dummy layers DWp is larger than the area of the copper wiring CW parts overlapping in the stacking direction.

Further, the plurality of dummy layers DWy are disposed in the region between the plugs V0 connected to the contacts CC and C3, respectively and overlap in the stacking direction with the parts of the copper wiring CW and the electrode pads PDm and PDc that are disposed in the peripheral region PR of the semiconductor storage device 1 and that do not overlap with the wiring layers M0, M1, plugs V0, V1, etc., as described above. The area of these dummy layers DWy is larger than the area of the copper wiring CW parts and the electrode pad PDm, PDc parts overlapping in the stacking direction.

Further, the dummy layer DWc is disposed on the upper end of the contact C3, and overlaps in the stacking direction with the copper wiring CW parts below the contact C3, which do not overlap with the wiring layers M0 and M1, the plugs V0 and V1, etc. connected to the contact C3, as described above. The area of the dummy layer DWc is larger than the area of the copper wiring CW parts overlapping in the stacking direction.

Further, the dummy layer DWe overlaps in the stacking direction with part of the copper layer CWe that is disposed at the upper end of the edge seal ESm, and is a part of the edge seal ESc, which does not overlap with the tungsten layer portion of the edge seal ESm, as described above. That is, the dummy layer DWe is disposed in a frame shape, for example, like the copper layer CWe that is a part of the edge seal ESc, and the area of the dummy layer DWe is larger than the area of the copper layer CWe overlapping in the stacking direction.

As described above, the copper wirings of the wiring layer M2, . . . , the plug V2, . . . , the electrode pads PDc and PDm, the wiring layers D1, D2, . . . , and the vias C1, C2, . . . , etc. are covered with any one of tungsten wirings such as the word lines WL, the bit lines BL, the wiring layers MX, M0, and M1, the plugs CH, V0, and V1, the wiring layer D0, and the contact CS, and the tungsten layers such as the dummy layers DWp, DWy, DWc, and DWe.

### Method for Manufacturing Semiconductor Storage Device

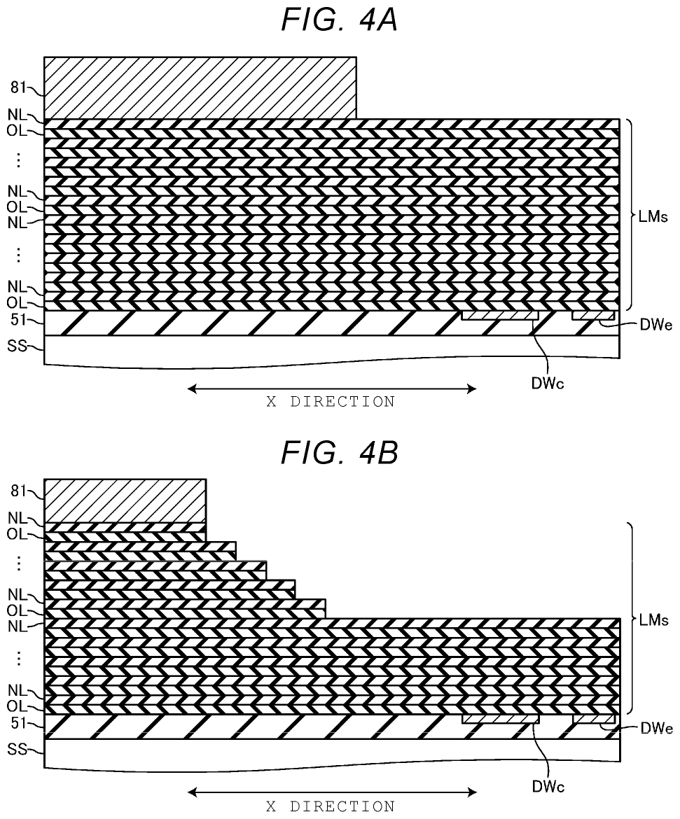

Next, a method for manufacturing the semiconductor storage device 1 of the embodiment will be described with reference to FIGS. 4 to 17.

FIGS. 4 to 16 are diagrams sequentially showing a part of the procedure of the method for manufacturing the semiconductor storage device 1 according to an embodiment. In each of FIGS. 4 to 16, the processed surface of the semiconductor storage device 1 in each process is shown facing upward in the paper. In addition, in the following description of the method for manufacturing the semiconductor storage device 1, for convenience of explanation, the direction that the processing surface is facing in each process is referred to as the upper side.

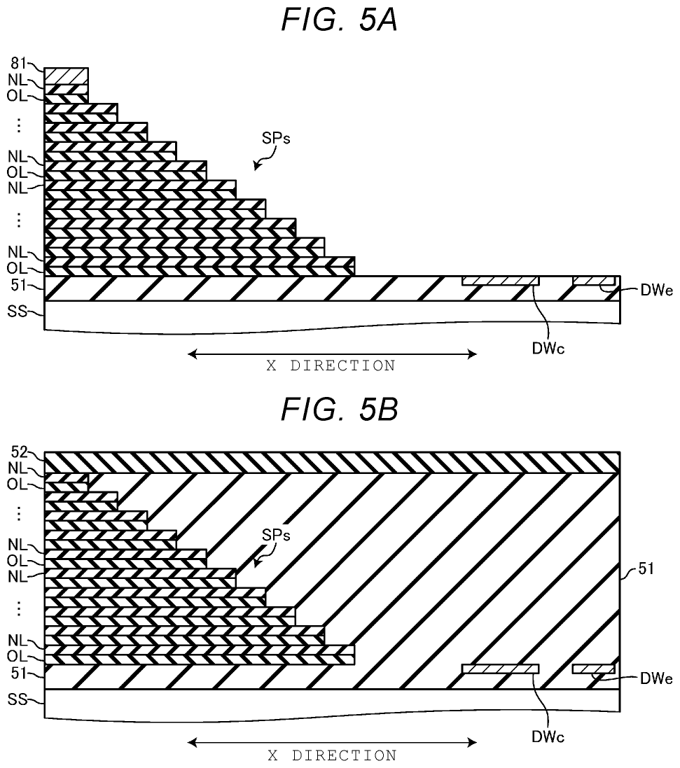

First, the states in which the portions SPa, which are later formed into the staircase portion SP, are formed are shown in FIGS. 4 and 5. FIGS. 4 and 5 show cross sections of the staircase region SR and the peripheral region PR along the X direction during manufacture.

As shown in FIG. 4A, the insulating layer 51 is formed on a supporting substrate SS such as a silicon substrate. Furthermore, in the area corresponding to the peripheral region PR, a recess (not shown) is formed on the upper surface of the insulating layer 51 and filled with a tungsten layer or the like to form dummy layers DWc and DWe that will later be connected to the contact C3 and the edge seal ESm.

The stacked body LMs in which a plurality of insulating layers NL and a plurality of insulating layers OL are alternately stacked one layer at a time is formed on the insulating layer 51 on which the dummy layers DWc and DWe are formed. The insulating layer NL is a silicon nitride layer, for example, and serves as a sacrifice layer that will later be replaced by the word line WL.

A mask pattern 81 is formed on the stacked body LMs to cover a part of the stacked body LMs. The mask pattern 81 is formed by exposing and developing a photoresist layer, etc., for example.

As shown in FIGS. 4B to 5A, slimming of the mask pattern 81 and etching of the insulating layer NL and the insulating layer OL of the stacked body LMs are repeated multiple times.

That is, the end portion of the mask pattern 81 is disposed at a position where the lowest step of the staircase portion SP is planned to be formed. Furthermore, the uppermost insulating layer NL and insulating layer OL are removed by etching, one layer at a time, for example, from the stacked body LMs exposed from the mask pattern 81. Further, by a treatment using oxygen plasma or the like, the end portion of the mask pattern 81 is retreated to newly expose the stacked body LMs, and the insulating layer NL and the insulating layer OL are further etched away, one layer at a time.

By repeating the above process multiple times, the insulating layer NL and the insulating layer OL are processed into a staircase shape at the end position of the mask pattern 81 to form staircase portions SPs, which are later formed into the staircase portions SP. After the staircase portions SPs are formed, the mask pattern 81 is removed by ashing using oxygen plasma or the like.

As shown in FIG. 5B, the insulating layer 51 is stacked up to cover the staircase portions SPs and reach the height position of the upper surface of the unprocessed stacked body LMs. Further, the insulating layer 52 is formed to cover the upper surface of the unprocessed stacked body LMs and the insulating layer 51 of the staircase portions SPs.

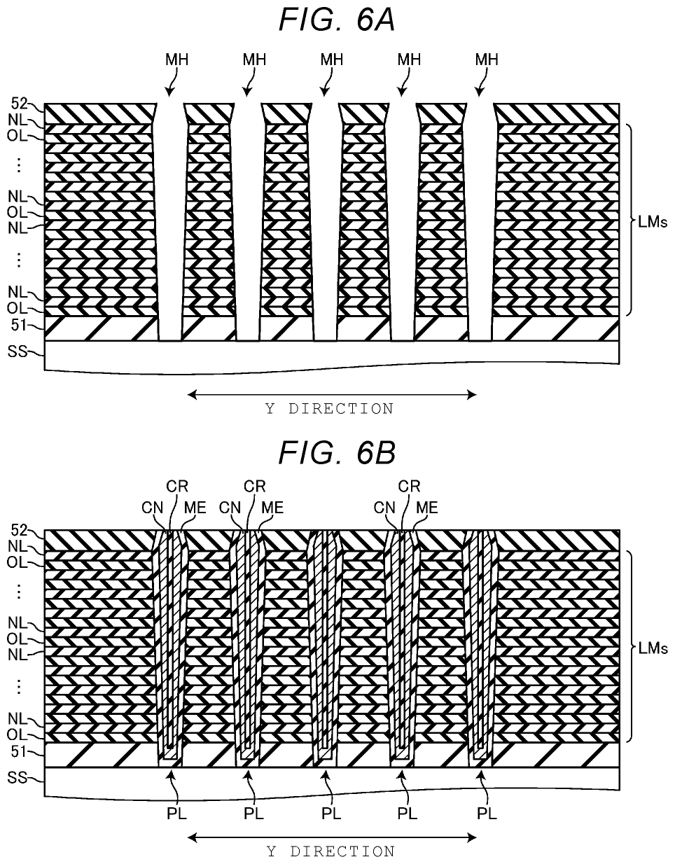

Next, FIG. 6 shows the state in which the pillars PL are formed. FIG. 6 shows a cross section of the memory region MR along the Y direction during manufacture.

As shown in FIG. 6A, the insulating layer 51, the stacked body LMs, and the insulating layer 52 are also formed in this order on the supporting substrate SS in a region that will later be formed into the memory region MR by the process illustrated in FIGS. 4 and 5 described above. Next, a plurality of memory holes MH are formed that penetrate the insulating layer 52, the stacked body LMs, and the insulating layer 51 and reach the supporting substrate SS.

As shown in FIG. 6B, the block insulating layer BK, the charge storage layer CT, and the tunnel insulating layer TN (see FIG. 2B) are stacked in this order on the sidewall and bottom surface of the memory hole MH via an etch stopper layer RS (not shown) to form the memory layer ME. As described above, the block insulating layer BK and the tunnel insulating layer TN are silicon oxide layers, and the charge storage layer CT is a silicon nitride layer, for example. Further, the etch stopper layer RS is a silicon oxynitride layer, for example.

Furthermore, a channel layer CN such as a polysilicon layer or an amorphous silicon layer is formed on the sidewall and bottom surface of the memory hole MH via the memory layer ME. Furthermore, the void of the memory hole MH remaining inside the channel layer CN is filled with a core layer CR such as a silicon oxide layer.

Through the above process, a plurality of pillars PL are formed. Meanwhile, at this stage, the memory layer ME is closed at the lower end, and the pillar PL does not have the active layer EP at the lower end.

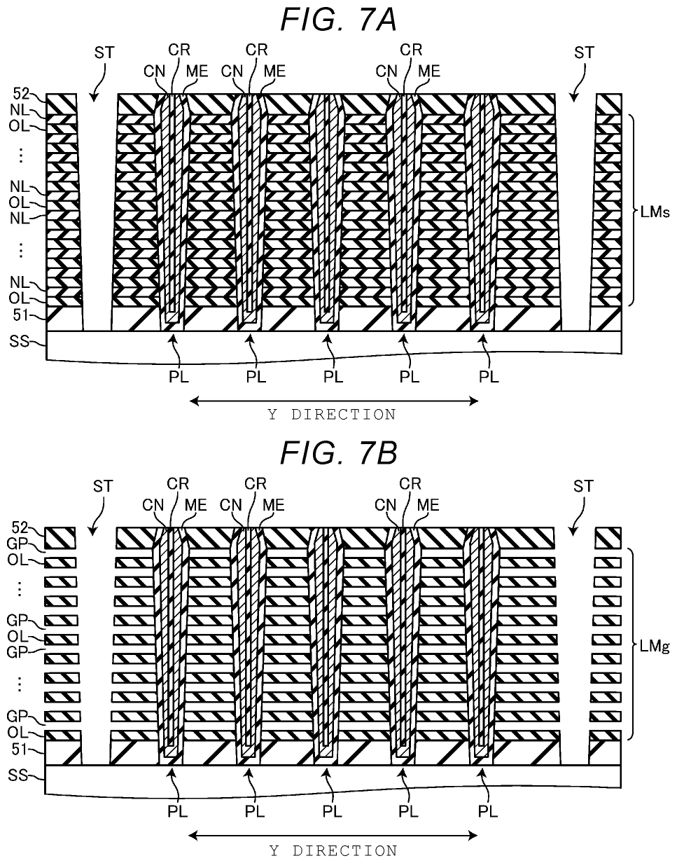

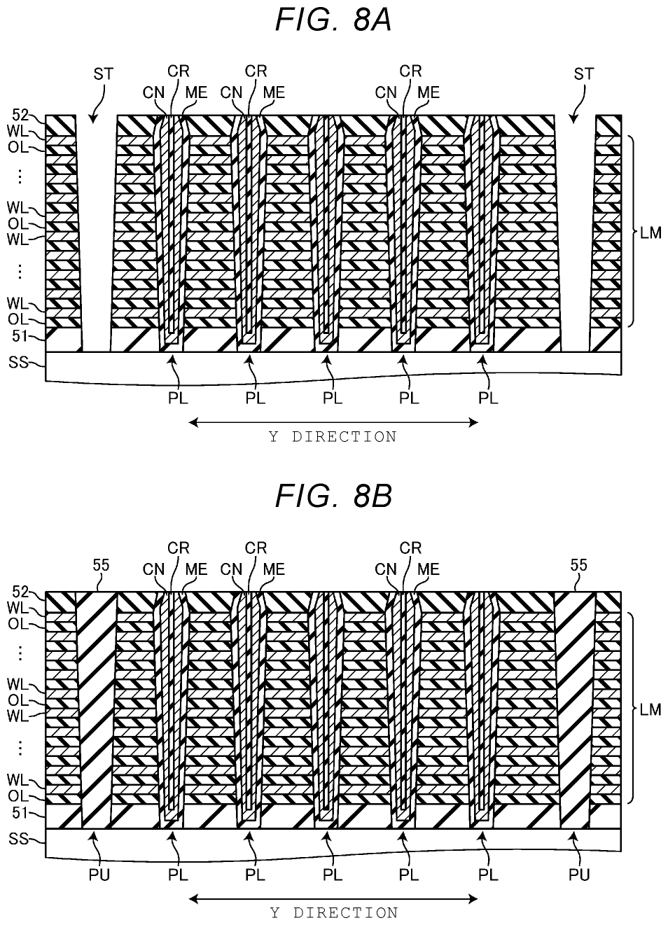

Next, FIGS. 7 and 8 show the state in which the word lines WL are formed. FIGS. 7 and 8 also show a cross section of the memory region MR along the Y direction during manufacture.

As shown in FIG. 7A, a plurality of slits ST are formed to penetrate the insulating layer 52, the stacked body LMs, and the insulating layer 51 and reach the supporting substrate SS. The plurality of slits ST also extend in the direction along the X direction in the stacked body LMs.

As shown in FIG. 7B, the insulating layer NL of the stacked body LMs is removed by flowing a removing liquid for the insulating layer NL, such as hot phosphoric acid, into the stacked body LMs from the slits ST penetrating the stacked body LMs. As a result, a stacked body LMg having a plurality of gap layers GP where the insulating layers NL between the insulating layers OL are removed is formed.

At this time, the silicon oxide layer such as the insulating layer OL may also be slightly dissolved by the removing liquid for the insulating layer NL. Therefore, the thickness of the insulating layer OL at the time of forming the stacked body LMs is determined in advance such that the desired layer thickness is maintained after the treatment with the removing liquid.

Furthermore, after the plurality of insulating layers NL are removed, the outer edge parts of the pillars PL are also exposed to the removing liquid for the insulating layers NL. As described above, by providing the etch stopper layer ES on the outermost periphery of the pillar PL, removal of the memory layer ME by the removing liquid for the insulating layer NL is prevented.

It is to be noted that the stacked body LMg including the plurality of gap layers GP has a fragile structure. In the memory region MR, the stacked body LMg, which is fragile, is supported by a plurality of pillars PL, for example. Furthermore, a plurality of dummy pillars (not shown) penetrating the stacked body LMs are formed in the staircase regions SR, and the staircase regions SR of the stacked body LMs can be supported by these dummy pillars.

These support structures prevent the remaining insulating layer OL from being bent and prevent the stacked body LMg from being distorted or collapsed.

As shown in FIG. 8A, a raw material gas of a conductive material such as tungsten or molybdenum is injected into the stacked body LMg from the slit ST, and the gap layers GP of the stacked body LMg are filled with the conductive material to form a plurality of word lines WL. As a result, the stacked body LM is formed, in which a plurality of word lines WL and a plurality of insulating layers OL are alternately stacked one layer at a time.

As described above, the process of forming the word lines WL from the insulating layer NL is also called a replacement process.

As shown in FIG. 8B, the slits ST are filled with the insulating layer 55 to form the plate-shaped parts PU.

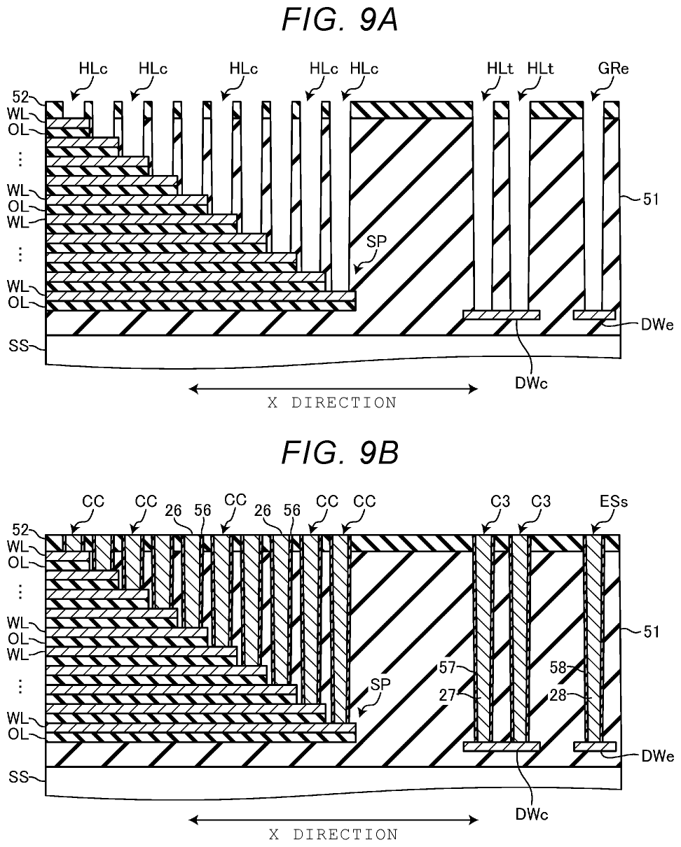

Next, FIG. 9 shows the state in which the contacts CC are formed in the staircase portions SP. Like FIGS. 4 and 5 described above, FIG. 9 shows a cross section of the staircase regions SR and peripheral regions PR along the X direction during manufacture.

As shown in FIG. 9A, by the process shown in FIGS. 7 and 8 described above, the insulating layers NL are replaced with the word lines WL even in the staircase regions SR which are in the middle of manufacturing, and the staircase portions SP are formed, in which a plurality of word lines WL are processed into a staircase shape.

Next, a plurality of contact holes HLc are formed to penetrate through the insulating layers 52 and 51 and reach the upper surface of each word line WL processed into the staircase shape. The contact hole HLc is a configuration that is to be the contact CC that will be connected to word line WL later.

Furthermore, in parallel with the formation of the contact holes HLc, contact holes HLt may be formed that penetrate the insulating layers 52 and 51 and reach the dummy layer DWc in a region corresponding to the peripheral region PR. The contact holes HLt are configurations that are to be the contacts C3 that will be connected to the source side wiring layer SL (see FIG. 2B) via the dummy layer DWc later.

Furthermore, in parallel with the formation of these contact holes HLc and HLt, a frame-shaped groove GRe may be formed to penetrate through the insulating layers 52 and 51 and reach the dummy layer DWe. The groove GRe is a configuration that is to be a part of the edge seal ESm surrounding the stacked body LM later.

As shown in FIG. 9B, insulating layers 56, 57, and 58 are formed to cover the sidewalls of contact holes HLc and HLt and the groove GRe, respectively. It is to be noted that, for convenience of explanation, the insulating layers 56, 57, and 58 are given different reference numerals, but these insulating layers 56 to 58 may be formed all at once in the contact holes HLc, HLt, and the groove GRe.

Further, the spaces of the contact holes HLc, HLt, and the groove GRe remaining inside the insulating layers 56, 57, and 58 are respectively filled with the conductive layers 26, 27, and 28 such as the tungsten layers. It is to be noted that, for convenience of explanation, the conductive layers 26, 27, and 28 are given different reference numerals, but these conductive layers 26 to 28 may be formed all at once in the contact holes HLc, HLt, and the groove GRe.

Through the above processes, the contacts CC and C3 and a portion ESs of the edge seal ESm are formed. It is noted that, since the groove GRe, which is the portion ESs of the edge seal ESm, has a large difference in aspect ratio from the contact holes HLc and HLt, if all of these are formed at once, sufficient processing accuracy may not be obtained for each individual structure. Therefore, the contacts CC and C3 and the portion ESs of the edge seal ESm may each be formed separately.

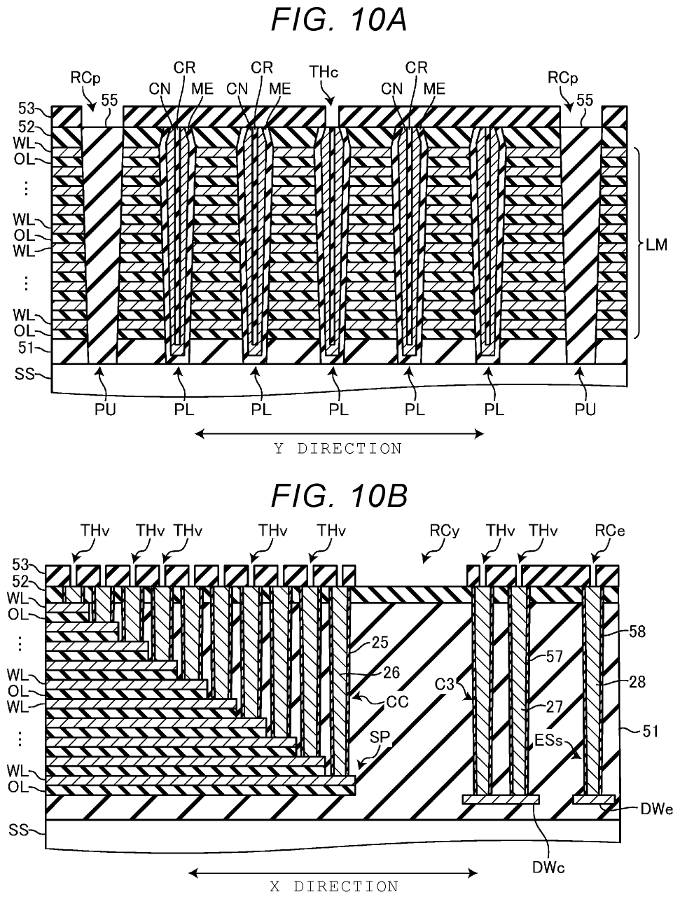

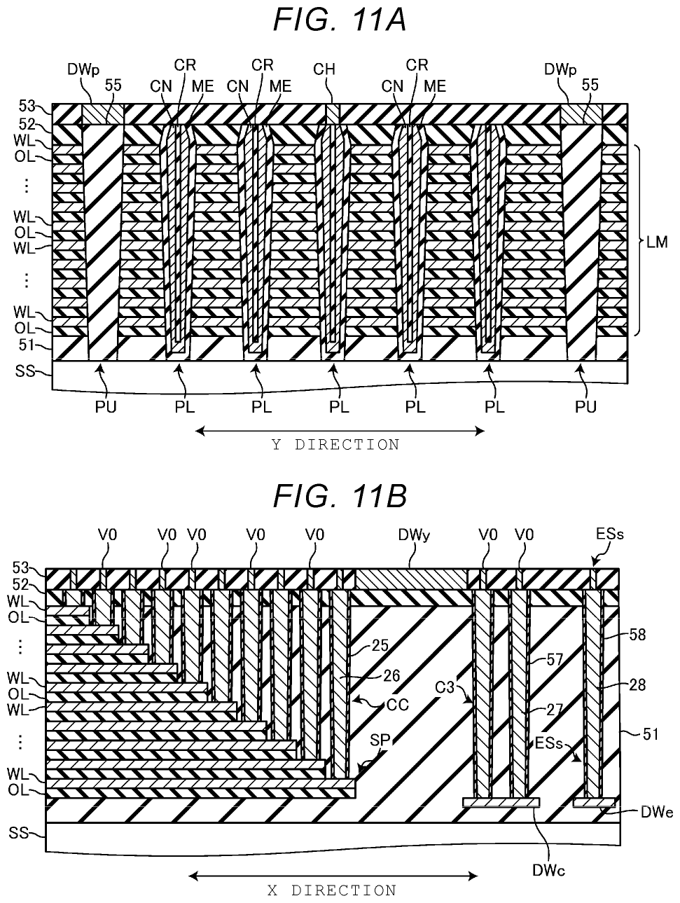

Next, FIGS. 10 and 11 show states in which the dummy layers DWp and DWy are formed together with the plugs CH and V0 disposed in the same layer as these.

Like FIGS. 6 to 8 described above, FIGS. 10 and 11A show a cross section of the memory region MR along the Y direction during manufacture. Like FIG. 9 and the like described above, FIG. 10 and FIG. 11B show cross sections of the staircase regions SR and the peripheral regions PR along the X direction during manufacture.

As shown in FIGS. 10A and 10B, the insulating layer 53 is formed on the insulating layer 52.

Furthermore, in the memory region MR shown in FIG. 10A, a plurality of through via holes THc that penetrate the insulating layer 53 and reach the upper ends of each of the plurality of pillars PL, and a plurality of recesses RCp that penetrate the insulating layer 53 and reach a predetermined position of the plate-shaped parts PU are formed. Here, the predetermined position of the plate-shaped parts PU is a position where the dummy layer DWp is to be disposed later (see FIG. 2C).

Moreover, in the staircase region SR shown in FIG. 10B, in parallel with the process shown in FIG. 10A, a plurality of through via holes THv that penetrate the insulating layer 53 and reach the upper ends of the plurality of contacts CC and C3, and a recess RCe that penetrates the insulating layer 53 and reaches the upper end of the portion ESs of the edge seal ESm are formed.

In addition, in parallel with the formation of these through via holes THv and the recess RCe, a plurality of recesses RCy are formed at predetermined positions in the insulating layer 53 in the region between the through via holes THv reaching the plurality of contacts CC and C3. Here, the predetermined position in the insulating layer 53 is a position where the dummy layer DWp is to be disposed later (see FIG. 2C).

As shown in FIG. 11A, a tungsten layer or the like is filled in the through via holes THc and the recess RCp, and a plurality of plugs CH connected to the channel layers CN of the plurality of pillars PL, respectively, and the dummy layers DWp disposed at the upper ends of the plate-shaped parts PU are respectively formed.

As shown in FIG. 11B, in parallel with the process shown in FIG. 11A, the through via holes THv are filled with the tungsten layer or the like, and a plurality of plugs V0 respectively connected to the conductive layers 26 and 27 of the plurality of contacts CC and C3 are formed. At this time, the recess RCe is also filled with the tungsten layer or the like, and the upper end of the portion ESs of the edge seal ESm extends to the upper surface of the insulating layer 53.

Further, in parallel with the formation of the plugs V0 and the like, the tungsten layer and the like are filled in the recesses RCy to form a plurality of dummy layers DWy.

In this way, the dummy layers DWp and DWy are formed all at once in parallel with the plugs CH, V0, etc. belonging to the same layer, for example. In other words, the dummy layers DWp, DWy, DWc, and DWe are preferably tungsten layers, etc., and by arranging at least part of the dummy layers DWp, DWy, DWc, and DWe on the same layer as the tungsten wiring such as the plugs CH and V0, these can be formed all at once.

Then, while further forming the insulating layer 54 on the insulating layer 53, the bit lines BL, the wiring layers MX, M0, M1, M2, . . . , the plugs CH, V0, V1, V2, . . . , the electrode pads PDm, etc. are sequentially formed.

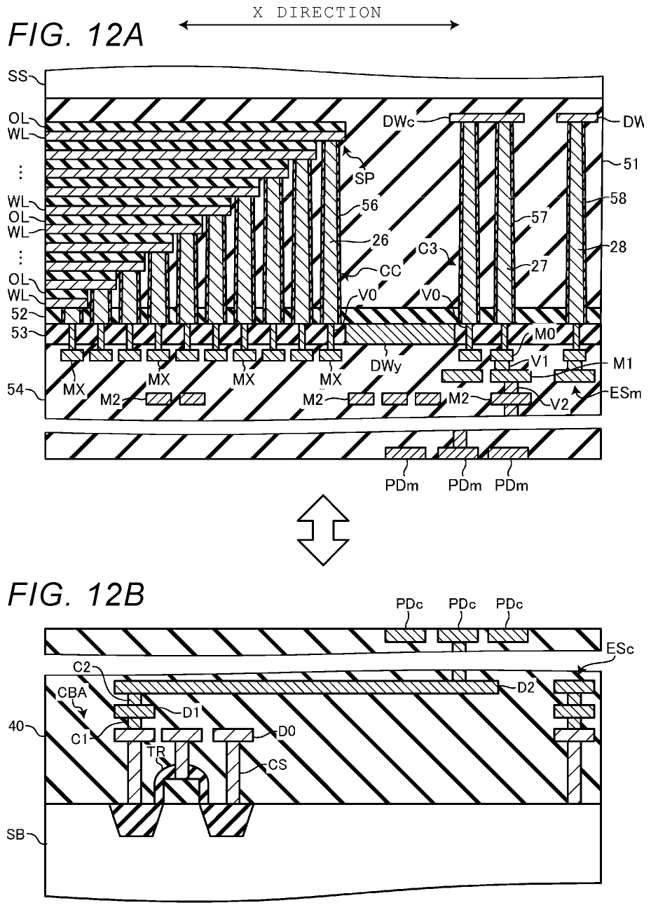

Next, FIG. 12 shows states in which the supporting substrate SS with the stacked body LM etc. formed thereon, and the semiconductor substrate SB with the peripheral circuit CBA etc. formed thereon are joined. FIG. 12 shows a cross section, along the X direction, of the supporting substrate SS with the stacked body LM and the like formed thereon, and the semiconductor substrate SB with the peripheral circuit CBA and the like formed thereon.

As shown in FIG. 12B, the peripheral circuit CBA including the transistor TR is formed on the semiconductor substrate SB separate from the supporting substrate SS. Further, while forming the insulating layer 40 covering the peripheral circuit CBA on the semiconductor substrate SB, the wiring layers D0, D1, D2, . . . , the contacts CS and the vias C1, C2, . . . , the electrode pads PDc, etc. are sequentially formed.

As shown in FIG. 12A, the supporting substrate SS with various configurations formed in the stacked body LM, and with the bit lines BL, the wiring layers MX, M0, M1, M2, . . . , the plugs CH, V0, V1, V2, . . . , etc. formed therein is placed such that a side of the supporting substrate SS on which the electrode pads PDm are formed is faced with a side of the semiconductor substrate SB on which the electrode pads PDc are formed.

Further, the insulating layer 54 on the supporting substrate SS side and the insulating layer 40 on the semiconductor substrate SB side are joined to each other. These insulating layers 54 and 40 can be joined by activating them in advance by plasma treatment, etc., for example. Furthermore, when joining the insulating layers 54 and 40, the supporting substrate SS and the semiconductor substrate SB are aligned with each other such that the electrode pads PDm formed on the insulating layer 54 and the electrode pads PDc formed on the insulating layer 40 overlap with each other.

After joining the insulating layers 54 and 40, an annealing process is performed to join the electrode pads PDm and PDc by Cu—Cu joining, for example. Accordingly, the supporting substrate SS and the semiconductor substrate SB are bonded to each other.

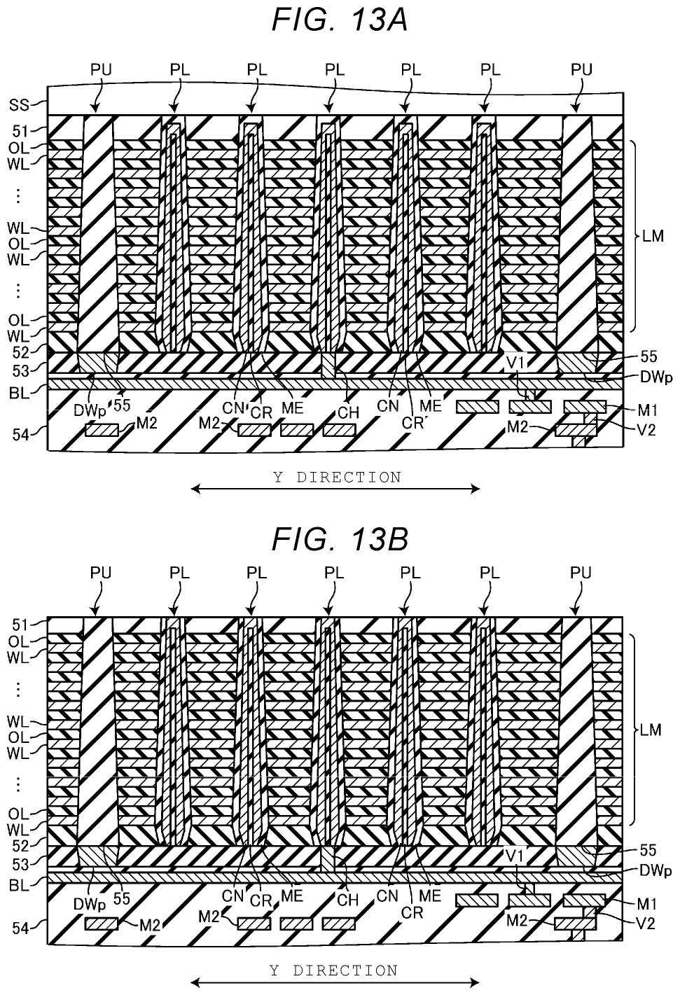

Next, FIGS. 13 to 17 show states in which the active layers EP are formed on the pillars PL.

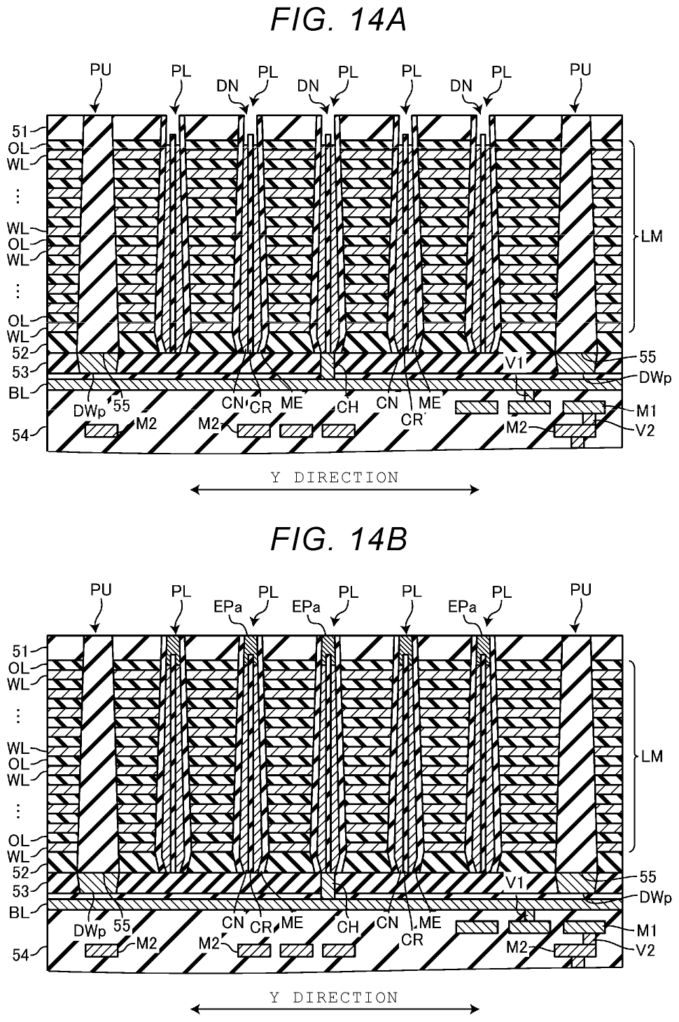

Like FIGS. 10 and 11A described above, FIGS. 13 and 14 show cross sections of the memory region MR along the Y direction during manufacture.

As shown in FIG. 13A, in the subsequent processes, various treatments are performed with the supporting substrate SS side facing upward, with the surface on the supporting substrate SS side being used as the processing surface.

As shown in FIG. 13B, the entire supporting substrate SS and part of the insulating layer 51 above the stacked body LM are removed by the chemical mechanical polishing (CMP) or the like. As a result, the upper ends of the pillars PL and the plate-shaped parts PU are exposed on the polished upper surface of the insulating layer 51. Further, the entire memory layer ME that covered the upper surface of the pillar PL and a part of the upper end of the channel layers CN are removed, and the channel layers CN are exposed from the upper ends of the pillars PL.

As shown in FIG. 14A, recess etching is performed on the exposed channel layers CN while maintaining a selectivity with respect to the memory layers ME covering the sidewalls of the pillars PL, and the upper ends of the channel layers CN are retreated in the depth direction of the pillars PL. As a result, recesses DN are formed at the upper ends of the pillars PL.

In addition, by maintaining a selectivity with respect to the memory layer ME during recess etching, it is also possible to prevent the insulating layer 51 containing the same type of material as the memory layer ME from being etched away. Furthermore, by obtaining the selectivity with respect to the memory layer ME, the core layers CR containing the same type of material as the memory layers ME may protrude into the recesses DN.

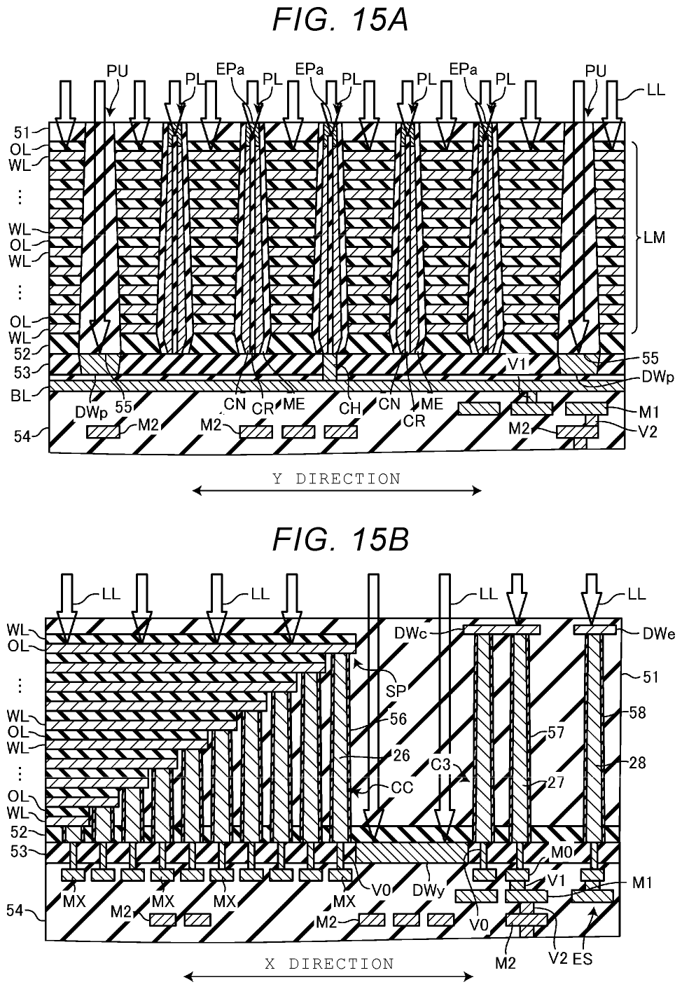

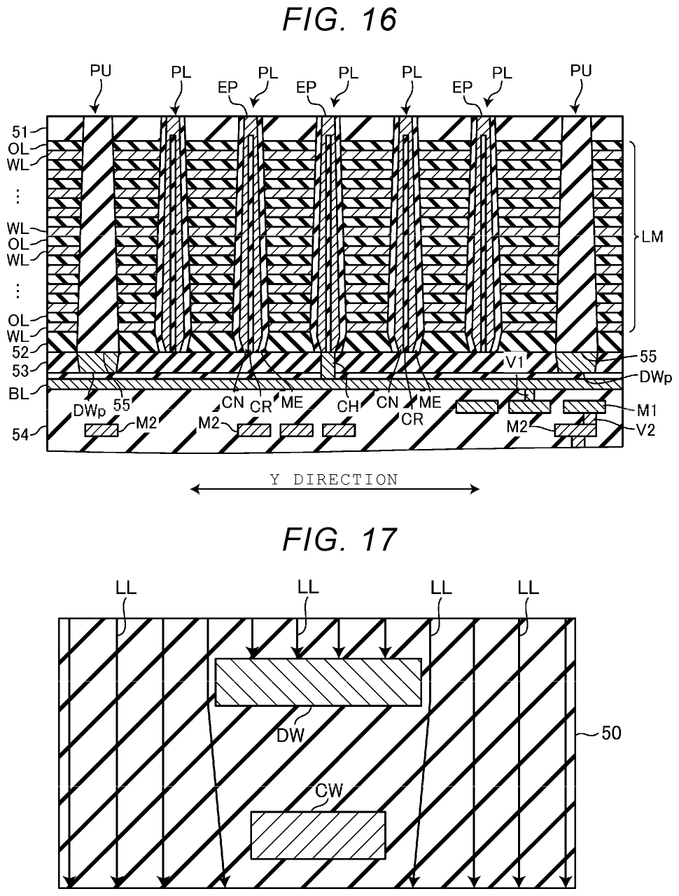

As shown in FIG. 14B, the recesses DN at the upper ends of the pillars PL are filled with semiconductor layers EPa such as an amorphous silicon layer or a polysilicon layer. Further, the semiconductor layers EPa are doped with a dopant such as phosphorus by ion implantation or the like. Further, as shown in FIGS. 15 and 16 below, dopants in the semiconductor layer EPa are activated by activation annealing.

Like FIGS. 10 and 11A described above, FIGS. 15A and 16 show cross sections of the memory region MR along the Y direction during manufacture. Like FIGS. 10 and 11B described above, FIG. 15B shows a cross section of the staircase regions SR and peripheral regions PR along the X direction during manufacture.

As shown in FIG. 15A, the semiconductor layer EPa is heated by irradiating laser light LL or the like from above the stacked body LM. As the laser light LL is irradiated to the semiconductor layer EPa, light in an ultraviolet wavelength range such as an excimer laser may be used, for example.

For example, laser light LL in the ultraviolet wavelength range is easily reflected or absorbed by the metal layers, and almost never passes through the metal layers. Meanwhile, an insulating layer such as a silicon oxide layer has a property of transmitting the laser light LL. Therefore, when the metal layer is irradiated with the laser light LL either directly or through an insulating layer such as a silicon oxide layer, the metal layer reflects or absorbs the laser light LL and is heated by the laser light LL.

Of the metals contained in the bit lines BL, the wiring layers MX, M0, M1, M2, . . . , the plugs CH, V0, V1, V2, . . . , the electrode pads PDc and PDm, the wiring layers D0, D1, D2, . . . , the contacts CS and vias C1, C2, etc. in the semiconductor storage device 1, tungsten is a metal with a high melting point and low atomic mobility and copper is a metal with a low melting point and high atomic mobility, as described above.

Therefore, even when the tungsten wiring in the semiconductor storage device 1 is irradiated with the laser light LL and heated, it is prevented from melting or diffusing into the insulating layers 40 and 50. Meanwhile, when the copper wiring in the semiconductor storage device 1 is irradiated with the laser light LL and heated, there is a risk that the copper wiring may be damaged by melting or diffusing into the insulating layers 40 and 50.

As shown in FIGS. 15A and 15B, when the laser light LL is irradiated from above the stacked body LM, most of the laser light LL irradiated onto the memory region MR and the staircase region SR is reflected or absorbed by the word lines WL of the stacked body LM. Meanwhile, since the plate-shaped parts PU that divide the word lines WL in the Y direction have a configuration including the insulating layer 55, the plate-shaped parts PU transmit the laser light LL.

However, the laser light LL that passed through the insulating layer 55 of the plate-shaped parts PU and proceeded below the stacked body LM is reflected or absorbed by the lower wiring layers MX, M0, and M1 of the stacked body LM or the plugs CH, V0, and V1 before reaching the copper wirings such as the wiring layers M2, . . . , the plugs V2, . . . , the wiring layers D1, D2, . . . , and the vias C1, C2, . . . , which are susceptible to damage by the laser light LL. Moreover, the laser light LL that travels to the part of the copper wirings that do not overlap with these tungsten wirings in the stacking direction is reflected or absorbed by the dummy layers DWp etc. disposed at the lower ends of the plate-shaped parts PU.

As shown in FIG. 15B, the laser light LL irradiated onto the peripheral region PR is reflected or absorbed by the lower wiring layers MX, M0, M1 of the stacked body LM or the plugs CH, V0, V1 before reaching the copper wirings such as the wiring layer M2, . . . , the plug V2, . . . , the electrode pads PDc and PDm, the wiring layers D1, D2, . . . , and the vias C1, C2, . . . , which are susceptible to damage by the laser light LL. Furthermore, the laser light LL that travels to the part of the copper wirings that do not overlap with these tungsten wirings in the stacking direction is reflected or absorbed by the dummy layers DWc and DWe disposed at the lower ends of the contacts C3 and the edge seals ESm, or by the dummy layers DWy disposed in the same layer as the plugs CH and V0, and the like.

As described above, any tungsten wiring or any dummy layer DWp, DWy, DWc, and DWe may prevent the laser light LL irradiated from above the stacked body LM from entering the copper wirings such as the wiring layer M2, . . . , the plug V2, . . . , the electrode pads PDc and PDm, the wiring layers D1, D2, . . . , and the vias C1, C2, . . . .

As shown in FIG. 16, dopants in the semiconductor layer EPa are activated by activation annealing using the laser light LL, and the active layer EP is formed at the lower end of each of the plurality of pillars PL.

Here, FIG. 17 shows in detail the state when the laser light LL is irradiated.

FIG. 17 is a schematic diagram showing the process of irradiating the laser light LL for a method for manufacturing the semiconductor storage device 1 according to an embodiment. FIG. 17 shows, as an example, a state in which the laser light LL is irradiated using the dummy layer DW and the copper wiring CW overlapping with the dummy layer DW in the stacking direction.

The dummy layer DW shown in FIG. 17 is one of the dummy layers DWp, DWy, DWc, and DWe described above, and the copper wiring CW is any copper wiring disposed in the layer below the wiring layer M1, like the copper wiring CW shown in FIG. 3 described above.

As shown in FIG. 17, most of the laser light LL irradiated onto the dummy layer DW is blocked by the dummy layer DW, as described above. At this time, part of the laser light LL that passed near both ends of the dummy layer DW in the width direction bends around to the lower surface side of the dummy layer DW due to the diffraction effect. As a result, at the lower position of the dummy layer DW, the shielding effect of the laser light LL can only be obtained in a region narrower than the actual width of the dummy layer DW.

However, as described above, the dummy layer DW is configured to have a larger area than the area of the corresponding part of the copper wiring CW to be shielded. This prevents the laser light LL bending around to the lower surface side of the dummy layer DW from entering the copper wiring CW.

Further, for example, as the vertical gap between the dummy layer DW and the copper wiring CW decreases, the heat of the dummy layer DW heated by the laser light LL is more likely to be transferred to the copper wiring CW. For this reason, the distance in the vertical direction between the dummy layer DW and the copper wiring CW to be shielded can be set to at least 100 nm or more, preferably 300 nm or more.

As described above, after the active layer EP is formed at the lower end of the pillar PL by irradiation with the laser light LL, the source side wiring layer SL is formed in a predetermined pattern on the insulating layer 51. At this time, the dummy layer DWc formed at the upper end of the contact C3 and the source side wiring layer SL are connected to each other. Further, the electrode layer EL is formed in a predetermined pattern on the source side wiring layer SL with the insulating layer 60 interposed therebetween. At this time, a part of the electrode layer EL is connected to the source side wiring layer SL by penetrating the insulating layer 60, and the pad region PD is formed in the electrode layer EL.

Further, the insulating layers 71 to 73 are formed in this order on the electrode layer EL, and the insulating layers 71 to 73 on the pad region PD of the electrode layer EL are removed to expose the pad region PD.

Through the above process, the semiconductor storage device 1 of the embodiment is manufactured.

### Overview

In the manufacturing process of semiconductor storage devices such as 3D nonvolatile memories, a process of forming an active layer at the upper end of a pillar where a memory cell is formed is sometimes performed by irradiating laser light from above, for example. At this time, there is a concern that a part of the laser light may pass through the insulating layer, damaging the low melting point copper wiring, etc. provided in the lower layer.

According to the semiconductor storage device 1 of the embodiment, a plurality of dummy layers DWy, DWc, and DWe are provided, which are disposed at positions higher than the height position of a plurality of copper wirings CW such as the wiring layers M2, . . . , the plugs V2, . . . , the electrode pads PDc and PDm, the wiring layers D1, D2, . . . , and the vias C1, C2, . . . , and disposed at positions overlapping in the stacking direction with parts of the plurality of copper wirings CW that do not overlap with the stacked body LM.

Accordingly, damage to the copper wirings CW due to irradiation with the laser light LL can be prevented. Moreover, the range in which the irradiation intensity of the laser light (LL) can be set is expanded, thereby making activation annealing easier.

According to the semiconductor storage device 1 of the embodiment, each of the plurality of dummy layers DWp, DWy, DWc, and DWe has a larger area when viewed from the stacking direction, than the parts of the plurality of copper wirings CW facing in the stacking direction via the insulating layers 50, 40, etc. of the copper wirings CW overlapping in the stacking direction.

Accordingly, it is possible to shield the part of the copper wiring CW where none of the bit line BL, the wiring layers MX, M0, and M1, or the plugs CH, V0, and V1 are disposed at a position overlapping in the stacking direction. Further, even when the laser light LL bends around to the lower surface side of the dummy layers DWp, DWy, DWc, and DWe due to the diffraction effect, a sufficient shielding effect can be obtained.

According to the semiconductor storage device 1 of the embodiment, the plurality of dummy layers DWp and DWy are disposed at the same height position as the plurality of plugs CH that electrically connect the pillars PL and one of the plurality of copper wirings CW. As a result, at least some of the dummy layers DWp and DWy can be formed together with the plurality of plugs CH, V0, etc., which are tungsten wiring, etc. with a high melting point and low atomic mobility.

According to the semiconductor storage device 1 of the embodiment, the plurality of dummy layers DWp are disposed at the lower ends of the plate-shaped parts PU. Accordingly, even in the region where the stacked body LM is disposed, the laser light LL that passed through the plate-shaped parts PU, which is the insulating layer 55, etc., is prevented from entering the copper wirings CW in the lower layer.

According to the semiconductor storage device 1 of the embodiment, the dummy layers DWc are disposed at the upper ends of the contacts C3, and connect the contacts C3 and the source side wiring layers SL. Accordingly, even in the region overlapping with the pad regions PD in the stacking direction, it is possible to prevent the laser light LL from entering the copper wirings CW in the lower layer. Further, the electrical connection between the contacts C3 and the source side wiring layers SL can be made stronger.

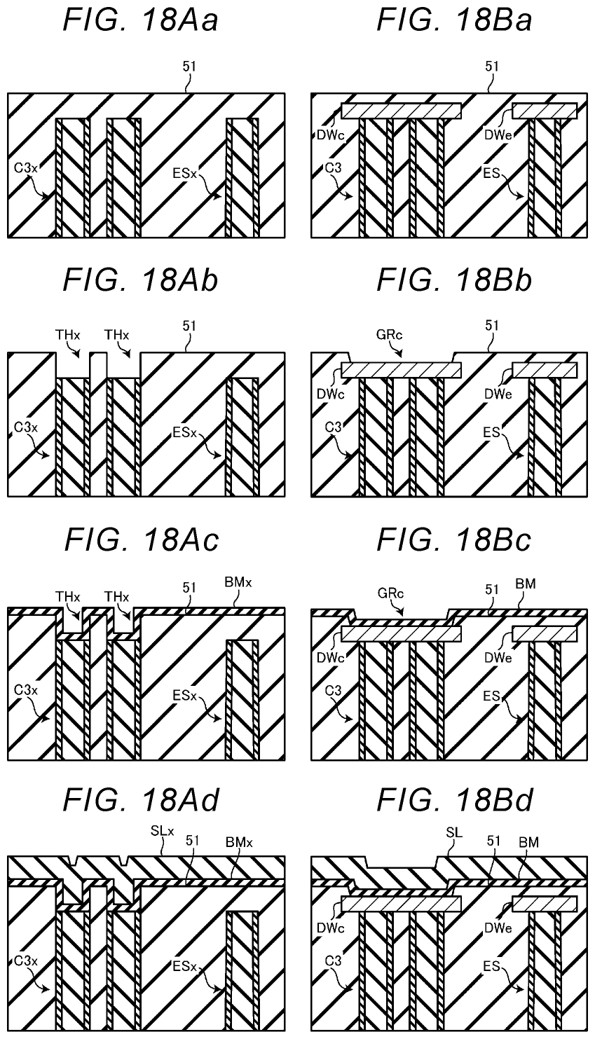

Hereinafter, the strengthened connection between the contacts C3 and the source side wiring layers SL by the dummy layers DWc will be described in more detail with reference to FIG. 18.

FIG. 18 is a cross-sectional view showing a part of a process of connecting the contacts and the source side wiring layers in a semiconductor storage device according to an embodiment and a comparative example.

As shown in FIG. 18Aa, in the semiconductor storage device of the comparative example, no dummy layer is formed at the upper ends of the contacts C3x and the edge seal ESx. In order to connect the contacts C3x to the source side wiring layer SLx, through via holes THx are formed to penetrate the insulating layer 51 and reach the upper ends of the contacts C3x as shown in FIG. 18Ab, a barrier metal layer BMx is formed on the upper surface of the insulating layer 51 and in the through via holes THx as shown in FIG. 18Ac, and a source side wiring layer SLx is formed by covering the upper surface of the insulating layer 51 and filling the through via holes THx with a tungsten layer or the like as shown in FIG. 18Ad.

As a result, the contacts C3x and the source side wiring layer SLx are electrically connected only at the tungsten layer portions at the bottom of the through via holes THx, and conduction can only be achieved in a very limited connection area. Furthermore, when forming the through via holes THx, there is a risk of misalignment with the contacts C3x, and in that case, the connection area between the contacts C3x and the source side wiring layer SLx further decreases.

As shown in FIG. 18Ba, in the semiconductor storage device 1 of the embodiment described above, dummy layers DWc and DWe are formed at the upper ends of the contacts C3 and the edge seal ES, respectively.

Therefore, in order to establish conduction between the contacts C3 and the source side wiring layer SL, as shown in FIG. 18Bb, a through groove GRc is formed that penetrates the insulating layer 51 and reaches the dummy layer DWc, for example. Further, the barrier metal layer BM is formed on the upper surface of the insulating layer 51 and in the through groove GRc as shown in FIG. 18Bc, and the source side wiring layer SL is formed by covering the upper surface of the insulating layer 51 and filling the through groove GRc with a tungsten layer or the like as shown in FIG. 18Bd.

As a result, the tungsten layer of the source side wiring layer SLx and the dummy layer DWc are connected to each other, and furthermore, an electrical connection with the contacts C3 can be obtained through the dummy layer DWc in a wide portion of the upper surface of the dummy layer DWc disposed straddling the upper ends of the plurality of contacts C3.

According to the semiconductor storage device 1 of the embodiment, the dummy layer DWe is disposed at the upper end of the edge seal ESm. This prevents the laser light LL from entering the copper layer portion of the edge seal ESc on the peripheral circuit CBA side, which is provided at a position overlapping with the edge seal ESm in the stacking direction.

As described above, the edge seal ESc itself does not contribute to the function of the semiconductor storage device 1. However, by providing the dummy layer DWe at the upper end of the edge seal ESm, it is possible to prevent the copper layer portion of the edge seal ESc from affecting other components of the semiconductor storage device 1 due to thermal diffusion or the like.

### Modifications

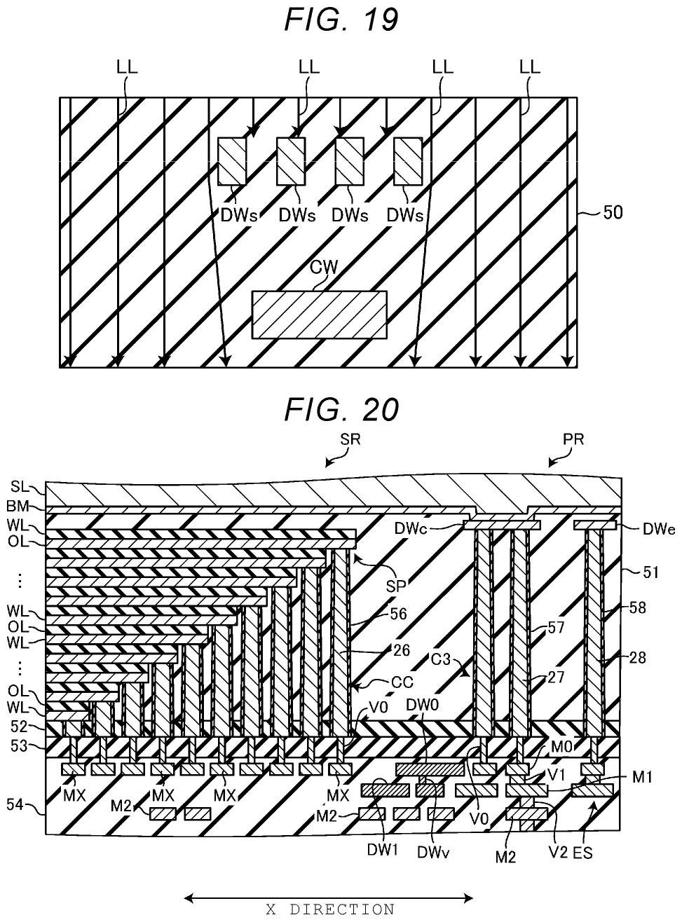

Next, semiconductor storage devices according to various modifications of the embodiment will be described with reference to FIGS. 19 to 21. It is to be noted that, in the subsequent drawings, the same components as those in the embodiments described above may be denoted by the same reference numerals, and duplicate description will be omitted.

FIG. 19 is a schematic diagram showing an example of the configuration of a dummy layer DWs in a semiconductor storage device according to a modification of the embodiment. The semiconductor storage device of the modification shown in FIG. 19 differs from the semiconductor storage device 1 of the embodiment described above in that it includes the dummy layer DWs divided into a plurality of pieces.

FIG. 19 shows, as an example, a state in which the laser light LL is irradiated, using a plurality of dummy layers DWs and a copper wiring CW overlapping with these dummy layers DWs in the stacking direction.

As shown in FIG. 19, the plurality of dummy layers DWs are divided into a plurality of pieces and disposed in a predetermined layer, that is, at the same height position and at a predetermined interval. The shape of each dummy layer DWs can be pad-like, dot-like, line-like, or the like, for example.

The area of the region where the plurality of dummy layers DWs are disposed is larger than the area of the portion to be shielded by the copper wiring CW. Further, the pitch of the plurality of dummy layers DWs can be made equal to or smaller than the wavelength of the laser light LL, or more preferably, sufficiently smaller than the wavelength of the laser light LL.

Accordingly, even when the dummy layer DWs is divided into a plurality of pieces and disposed, the laser light LL is prevented from passing through the plurality of dummy layers DWs and entering the copper wiring CW. In addition, since the dummy layer DWs is disposed in a wider range than the area of the shielding target portion of the copper wiring CW, the laser light LL that bends around to the lower surface side of the dummy layer DWs at the endmost part of the arrangement of the plurality of dummy layers DWs is prevented from entering the copper wiring CW.

At this time, when the pitch of the plurality of dummy layers DWs is sufficiently small, it is considered that the entire region where the plurality of dummy layers DWs are disposed has average physical properties of a plurality of dummy layers DWs disposed at predetermined intervals and the insulating layer 51 such as a silicon oxide layer positioned between these dummy layers DWs. That is, the entire region where the plurality of dummy layers DWs are disposed can be regarded as a homogeneous layer having a refractive index that is the average of the high refractive index tungsten layer and the low refractive index silicon oxide layer.

FIG. 20 is a cross-sectional view showing an example of another configuration of a semiconductor storage device according to a modification of the embodiment. The semiconductor storage device of the modification shown in FIG. 20 differs from the semiconductor storage device 1 of the embodiment described above in that the dummy layers DW0, DW1, and DWv are distributed and disposed in a plurality of layers.

As shown in FIG. 20, the semiconductor storage device of the modification includes the dummy layers DW0, DW1, and DWv in the region between the contacts CC and C3. These dummy layers DW0, DW1, and DWv are disposed in multiple layers in which the wiring layers MX, M0, and M1, plugs CH, V0, V1, etc. are disposed.

More specifically, the dummy layer DW0 is disposed in the same layer as the wiring layers MX and M0, for example. The dummy layer DW1 is disposed in the same layer as the wiring layer M1, for example. The dummy layer DW0 is an example of a third conductive layer, and the dummy layer DW1 is an example of a fourth conductive layer. Moreover, the wiring layers MX and M0 are an example of the second metal wiring layers, and the wiring layer M1 is an example of the third metal wiring layer.

Further, at least some of the dummy layers DW0 and DW1 may be connected by a dummy layer DWv disposed in the same layer as the plug V1 that connects the wiring layers M0 and M1.

In this way, by connecting the dummy layers DW0 and DW1 belonging to different layers with each other through the dummy layer DWv, the overall surface area of these dummy layers DW0, DW1, and DWv increases. Accordingly, it is possible to prevent heating of these dummy layers DW0, DW1, and DWv by the laser light LL, and it is possible to prevent the heat of the dummy layers DW0, DW1, and DWv from being transferred to the nearby copper wirings.

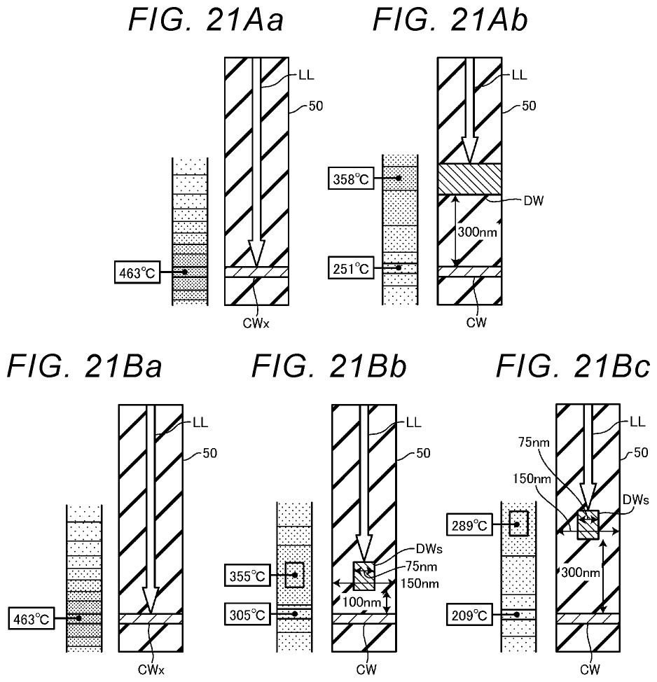

Here, the heat insulation effects of the various dummy layers DWy, DWs, DW0, and DW1 with respect to the copper wirings CW are shown in a schematic diagram in FIG. 21.

FIG. 21 is a schematic diagram showing analysis results of optical and heat transfer engineering simulations of the semiconductor storage device according to an embodiment, a modification, and a comparative example.

More specifically, FIGS. 21Aa and 21Ba show analysis results of a semiconductor storage device of the comparative example that does not have a dummy layer, FIG. 21Ab shows an analysis result of a semiconductor storage device having a dummy layer DW of the embodiment or the modification, and FIGS. 21Bband 21Bc show analysis results of a semiconductor storage device having a dummy layer DWs of the modification.

In the analysis of FIG. 21, the temperature of the dummy layers DW and DWs and the copper wirings CW and CWx was simulated when the laser light LL having a wavelength of 308 nm was irradiated with an energy amount of 0.213/cm².

As shown in FIGS. 21Aa and Ba, in the semiconductor storage device of the comparative example in which the laser light LL transmitted through the insulating layer 51 without the dummy layer is directly irradiated onto the copper wiring CWx, the result shows that the copper wiring CWx was heated to 463° C. In addition, when the temperature of the copper wiring CWx is 400° C. or higher, it is considered that there is a risk of damage to the copper wiring CWx.

The dummy layer DW shown in FIG. 21Ab is obtained by imitating one of the dummy layers DWp and DWy of the embodiment described above and the dummy layers DW0 and DW1 of the modification described above, and it is assumed that it is disposed at a height position of 300 nm above the copper wiring CW to be shielded.

As shown in FIG. 21Ab, under the conditions described above, even when the dummy layer DW was heated to 358° C. by irradiation with the laser light LL, the result shows that the heating of the copper wiring CW was prevented at 251° C.

The plurality of dummy layers DWs shown in FIGS. 21Bb and 21Bc each have a width of 75 nm in the left-right direction of the paper and a pitch of 170 nm.

As shown in FIG. 21Bb, when the dummy layer DWs is disposed at a height position of 100 nm above the copper wiring CW to be shielded, even when the dummy layer DWs was heated to 355° C. by irradiation with the laser light LL, the result shows that the heating of the copper wiring CW was prevented at 305° C.

As shown in FIG. 21Bc, when the dummy layer DWs is disposed at a height position of 300 nm above the copper wiring CW to be shielded, even when the dummy layer DWs was heated to 289° C. by irradiation with the laser light LL, the result shows that the heating of the copper wiring CW was prevented at 209° C.

From the above analysis results, the dummy layers DWp, DWy, DW0, DW1, and DWs can be disposed at least 100 nm or more above, and more preferably 300 nm or more above the copper wiring CW to be shielded. Furthermore, it can be seen that a sufficient shielding effect for the copper wirings CW can also be obtained by arranging the plurality of dummy layers DWs at a pitch equal to or less than the wavelength of the laser light LL.

According to the semiconductor storage device of the modification, the plurality of dummy layers DWs are divided into a plurality of pieces having a smaller area when viewed from the stacking direction, than the parts of the copper wiring CW facing in the stacking direction via the insulating layers 50 and 40, etc.

Accordingly, the degree of freedom in arranging the dummy layer DWs can be increased. In addition, the area of each dummy layer DWs can be reduced, and when forming the dummy layer DWs, dishing etc. can be avoided when removing an excess tungsten layer by CMP etc., thereby improving processing accuracy.

According to the semiconductor storage device of the modification, the region where the plurality of dummy layers DWs are disposed has a larger area than the parts of the copper wiring CW facing in the stacking direction via the insulating layers 50, 40, etc. Accordingly, even when the laser light LL bends around to the lower surface side of the dummy layer DWs due to the diffraction effect, a sufficient shielding effect can be obtained.

According to the semiconductor storage device of the modifications, a plurality of dummy layers DWs are disposed at a pitch equal to or less than the wavelength of the laser light LL. This prevents the laser light LL from passing through the plurality of dummy layers DWs and entering the copper wiring CW in the lower layer.

According to the semiconductor storage device of the modification, the plurality of dummy layers DW0 and DW1 are disposed at the height positions of the plurality of wiring layers MX and M0, and at the height position of the plurality of wiring layers M1, respectively. Accordingly, for example, it is possible to prevent the dummy layers DW0 and DW1 from being densely formed in the same layer, and the heat dissipation of the dummy layers DW0 and DW1 is promoted. Further, the degree of freedom in arranging the dummy layers DW0 and DW1 can be increased.

Furthermore, if the dummy layers DW0 and DW1 are connected to each other by the dummy layer DWv, the amount of heat between the dummy layers DW0 and DW1 can be distributed and made uniform.

### Other Modifications

In the embodiments and modifications described above, the wiring layer to be shielded is the copper wiring CW, and the dummy layers DWp, DWy, DW0, DW1, DWv, and DWs are the tungsten layers. However, for example, aluminum Al wiring, etc., which has a low melting point and high atomic mobility, may also be in the wiring layers to be shielded.

Further, as described above, a metal having at least one of the properties including a high melting point and a low atomic mobility may be used as the dummy layer. As an example, the dummy layer may be a metal layer such as a ruthenium Ru layer or a molybdenum layer Mo. Furthermore, it is also possible to use a semiconductor layer as a dummy layer.

For example, a molybdenum layer instead of the tungsten layer may be used for the word lines, and when the molybdenum layer is used for the dummy layer, it is preferable that the dummy layer be disposed on the same layer as the stacked body LM. Furthermore, if a ruthenium layer, a molybdenum layer, a semiconductor layer, or the like is not used for the word lines or the wiring layers, it is also possible to make the dummy layer separately from the word lines and wiring layers.

Furthermore, in the embodiments and modifications described above, the slits ST used in the replacement process are filled with the insulating layer 55 to form the plate-shaped parts PU that do not contribute to the function of the semiconductor storage device 1. However, the slits ST may be filled with the conductive layer and connected to the source side wiring layer SL, etc., to serve as the source line contacts.

Furthermore, in the embodiments and modifications described above, it may be the copper wiring to the plugs V2 on the upper layer side to the vias C1 on the lower layer side with the electrode pads PDm and PDc of the semiconductor storage device 1 interposed therebetween. However, in each layer between the pillars PL and contacts CC on the stacked body LM side and the peripheral circuit CBA on the semiconductor substrate SB side, the range where the copper wiring is used may vary as appropriate. For example, there may be the copper wiring up to the upper bit line BL with the electrode pads PDm and PDc interposed therebetween.

In this case, the dummy layers are appropriately disposed at positions overlapping in the stacking direction with the bit line BL etc. that newly require shielding.

Furthermore, in the embodiments and modifications described above, the stacked structure of the insulating layers NL and OL is formed in one process, resulting in the semiconductor storage device 1 having the stacked body LM having a 1-tier structure. However, the stacked body may have a 2-or higher-tier structure. By increasing the number of tiers of the stacked body, it is possible to increase the number of stacked word lines WL.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a substrate;
a plurality of transistors disposed on the substrate;
a first metal wiring layer disposed over the plurality of transistors at a first position in a first direction perpendicular to the substrate, the first metal wiring layer including a first metal wiring;
a stacked body, disposed above the first metal wiring layer, including a plurality of first conductive layers and a plurality of first insulating layers alternately stacked on top of one another in the first direction, wherein the stacked body is overlapped with the first metal wiring in the first direction;
a pillar including a semiconductor layer that includes a first type impurity in an upper end and penetrates through the stacked body in the first direction, wherein the semiconductor layer is electrically connected to the plurality of transistors via the first metal wiring; and
a second conductive layer disposed at a second position further from the substrate than the first position in the first direction, overlapped with the first metal wiring or another metal wiring in the first metal wiring layer in the first direction, and not electrically connected to any of the plurality of transistors, the plurality of first conductive layers, or the first metal wiring layer,
wherein the second conductive layer includes at least one of a metal layer or a semiconductor layer, the second conductive layer having a higher melting point than the first metal wiring.

2. The semiconductor storage device according to claim 1, wherein the second conductive layer faces at least a part of the first metal wiring in the first direction via a second insulating layer, and has a larger area than the part of the first metal wiring when viewed from the first direction.

3. The semiconductor storage device according to claim 1, wherein
the second conductive layer faces at least a part of the first metal wiring in the first direction with a second insulating layer interposed therebetween, and is divided into a plurality of pieces each having an area smaller than the part of the first metal wiring when viewed from the first direction, and
a region where the plurality of pieces are disposed has a larger area than the part of the first metal wiring when viewed from the first direction.

4. The semiconductor storage device according to claim 1, further comprising:
a second metal wiring layer disposed at a third position between the pillar and the first metal wiring in the first direction, and electrically connected to the pillar and the first metal wiring,
wherein the second metal wiring layer has a higher melting point than the first metal wiring, and
the second position is substantially aligned with the third position.

5. The semiconductor storage device according to claim 4, further comprising:
a plurality of plate-shaped parts extending in the stacked body in the first direction and in a second direction intersecting the first direction, and dividing the stacked body in a third direction intersecting the first direction and the second direction,
wherein the second conductive layer is disposed at respective lower ends of the plate-shaped parts.

6. The semiconductor storage device according to claim 4, further comprising:
a third metal wiring layer disposed at a fourth position between the pillar and the first metal wiring,
wherein
the third metal wiring layer has a higher melting point than the first metal wiring and disposed at the fourth position different from the first position, and
the second conductive layer includes a third conductive layer disposed at the third position and a fourth conductive layer disposed at the fourth position.

7. The semiconductor storage device according to claim 1, further comprising:
a contact extending in the first direction at a position laterally away from the stacked body and electrically connected to the plurality of first conductive layers and the plurality of transistors;
a second metal wiring disposed below the contact and overlapped with the contact in the first direction;
a fifth conductive layer disposed at a higher position than the stacked body in the first direction and overlapped with the second metal wiring in the first direction; and
a fourth metal wiring layer disposed at a higher position than the stacked body in the first direction and electrically connected to the contact,
wherein the fifth conductive layer includes at least one of a metal layer or a semiconductor layer, the fifth conductive layer having a higher melting point than the second metal wiring, and is disposed at an upper end of the contact to connect the contact and the fourth metal wiring layer.

8. A method for manufacturing a semiconductor storage device, the method comprising:
forming a plurality of transistors on a substrate;
forming a first metal wiring layer above the plurality of transistors at a first position in a first direction perpendicular to the substrate, wherein the first metal wiring layer includes a first metal wiring;
forming a stacked body above the first metal wiring layer, wherein the stacked body includes a plurality of first conductive layers and a plurality of first insulating layers alternately stacked on top of one another in the first direction, and is overlapped with the first metal wiring in the first direction;
forming a pillar having a semiconductor layer penetrating through the stacked body in the first direction; and
forming a second conductive layer by implanting a first type impurity into an upper end of the semiconductor layer and irradiating the stacked body with laser light, the second conductive layer at a second position further from the substrate than the first position in the first direction, wherein the second conductive layer is overlapped with the first metal wiring or another metal wiring in the first metal wiring layer in the first direction, and is not electrically connected to any of the plurality of transistors, the plurality of first conductive layers, or the first metal wiring layer,
wherein the second conductive layer includes at least one of a metal layer or a semiconductor layer, causing the second conductive layer to have a higher melting point than the first metal wiring.

9. The method for manufacturing a semiconductor storage device according to claim 8, wherein, when irradiating the laser light, the first metal wiring is blocked from being irradiated with the laser light using the plurality of first conductive layers or the second conductive layer.

10. The method for manufacturing a semiconductor storage device according to claim 8, further comprising, when forming the second conductive layer,
with at least a part of the first metal wiring facing in the first direction via a second insulating layer, dividing the second conductive layer into a plurality of pieces each having an area smaller than the part of the first metal wiring when viewed from the first direction; and
arranging the plurality of pieces over a region having a larger area than the part of the first metal wiring when viewed from the first direction.

11. The method for manufacturing a semiconductor storage device according to claim 10, further comprising, arranging the plurality of pieces separated from one another with a pitch that is equal to or less than a wavelength of the laser light.

12. The method for manufacturing a semiconductor storage device according to claim 8, further comprising:
further forming a second metal wiring layer electrically connected to the pillar and the first metal wiring, wherein the second metal wiring layer is disposed at a third position between the pillar and the first metal wiring, the second metal wiring layer has a higher melting point than the first metal wiring, and the second position is substantially aligned with the third position.

13. The method for manufacturing a semiconductor storage device according to claim 12, wherein the forming the second metal wiring layer and the forming the second conductive layer are performed in parallel.
